(19) United States
(12) Patent Application Publication
(10) Pub. No.: US 2026/0251859 A1
(43) Pub. Date: Aug. 27, 2026

(54) SEMICONDUCTOR PACKAGE AND METHODS OF MANUFACTURING THE SAME

(71) Applicant: Taiwan Semiconductor Manufacturing Company, Ltd., Hsinchu (TW)

(72) Inventors: Hung-Yi Kuo, Taipei City (TW); Chia-Yen Tan, Taoyuan City (TW); Zi-Jheng Liu, Taoyuan City (TW); Chieh-Wen Hsieh, Hsinchu City (TW); Yu-Chen Hu, Hsinchu City (TW); Yu-Min Liang, Taoyuan City (TW); Tsung-Ding Wang, Tainan (TW); Hao-Yi Tsai, Hsinchu City (TW)

(73) Assignee: Taiwan Semiconductor Manufacturing Company, Ltd., Hsinchu (TW)

(21) Appl. No.: 19/062,048

(22) Filed: Feb. 25, 2025

(51) Int. Cl. G02B 6/42; H01L 21/56; H01L 23/00; H01L 23/31; H01L 23/538; H01L 25/00; H01L 25/16

(52) U.S. Cl. CPC G02B 6/4214; H10W 70/611; H10W 74/01; H10W 90/00; H10W 90/401; H10W 74/141; H10W 90/792

(57) ABSTRACT

A semiconductor package includes an interposer, a semiconductor die, an optical die, a socket and a photonic component. The semiconductor die is disposed over the interposer. The optical die is disposed over the interposer and laterally next to the semiconductor die, where the optical die includes an edge coupler, a first reflector and a first lens structure optically coupled to the each other, the first reflector is laterally next to the edge coupler, and the first lens structure is vertically disposed over the first reflector. The socket is disposed over the optical die, where the optical die is between the socket and the interposer. The photonic component is removably installed onto the socket, where the photonic component includes a second reflector and a second lens structure optically coupled thereto, and the second reflector is vertically disposed over the second lens structure. The second lens structure and the first lens structure are overlapped with and optically coupled to each other.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 21 are schematic cross-sectional or plane views of various stages in manufacturing a semiconductor package in accordance with some embodiments of the disclosure.

FIG. 22 and FIG. 23 are respectively schematic cross-sectional and plane views of a semiconductor package in accordance with some alternative embodiments of the disclosure.

FIG. 24 and FIG. 25 are schematic cross-sectional views of a semiconductor package in accordance with some embodiments of the disclosure.

FIG. 26 is a schematic cross-sectional view of a semiconductor package in accordance with some alternative embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package (or a semiconductor device or structure) having a stacked structure with an optical die (or chip/chiplet/package) having a fiber socket equipped therein and a method of manufacturing the same, and is not intended to limit the scope of the disclosure. Due to the optical die with an edge coupler is directly integrated with the semiconductor package through an interposer included in the semiconductor package, a signal transmission path is reduced, thereby improving the performance of the semiconductor package by enabling the bandwidth enlargement, lower polarization sensitivity and faster data transfer. In addition, due to the fiber socket is integrated with the optical die, the alignment and the placement of an optical fiber (e.g., a fiber array unit (FAU)) can be accurate and precise, thereby improving the performance of the semiconductor package. In some embodiments of the disclosure, due to a reflector is equipped in the optical fiber (which a horizontal light is turned into a vertical light), another reflector (which a vertical light is turned into a horizontal light) is embedded into the optical die and a pair of a lens structure in the optical fiber and a lens structure in the optical die are cooperated with each other (for achieving focus), it allows the optical fiber to be vertically integrated with the optical die and still optically coupled to an edge coupler of such optical die, thereby not only simplifying the assembly of the optical fiber onto the optical die but also enhancing the flatness at a backside of the semiconductor package (which benefits the installation of heat dissipating elements). The manufacture of such semiconductor package in the disclosure is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

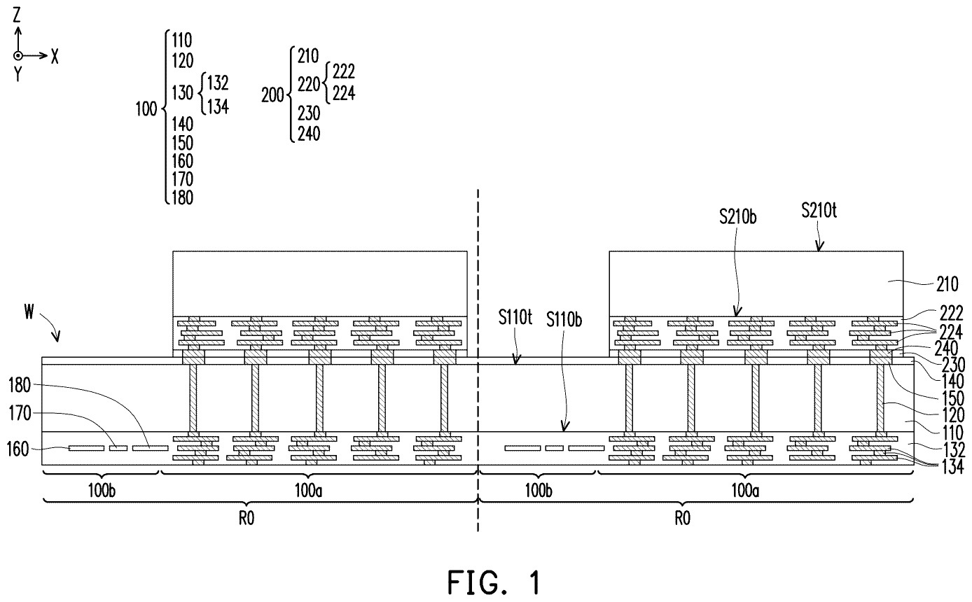

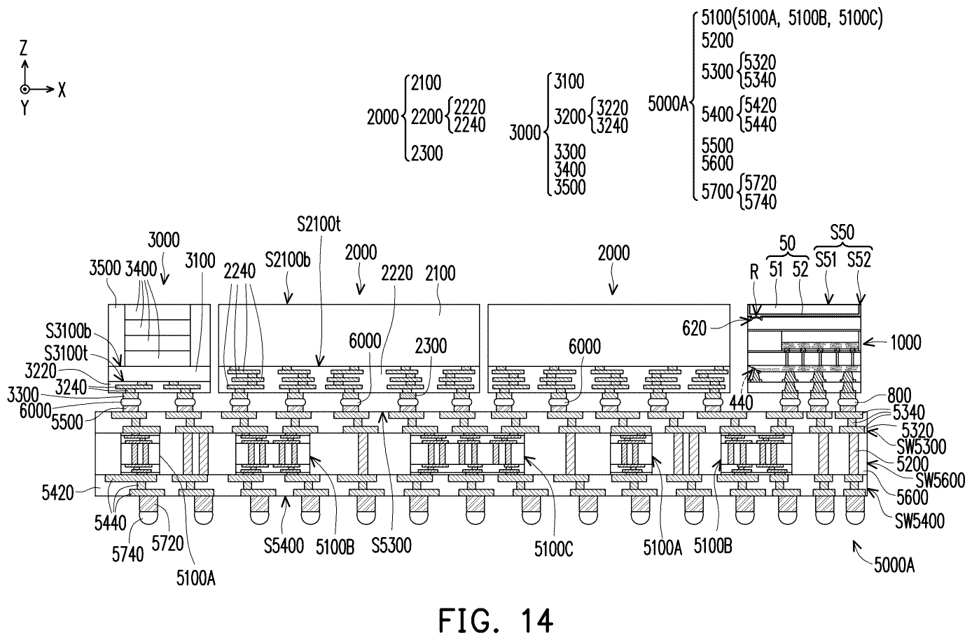

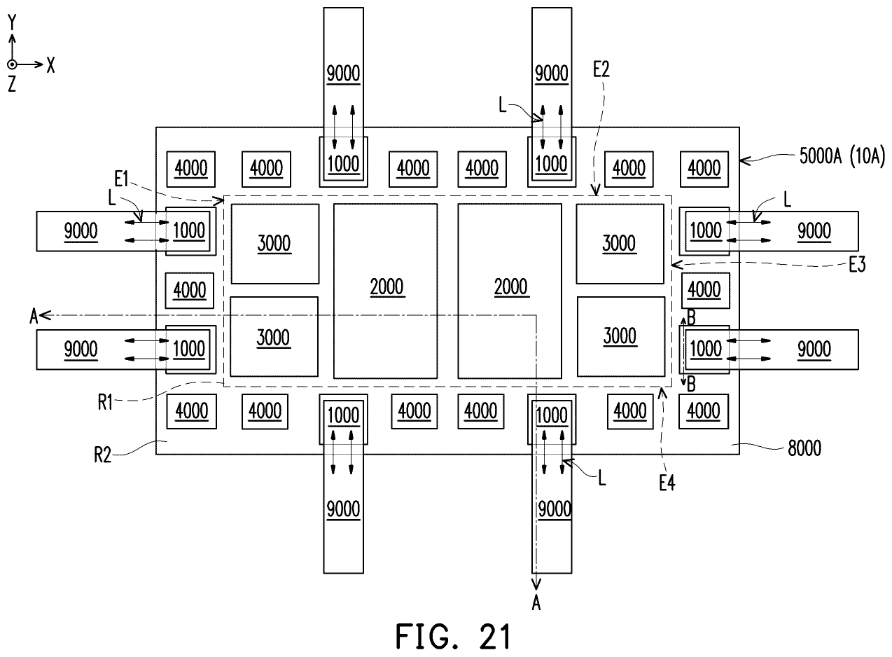

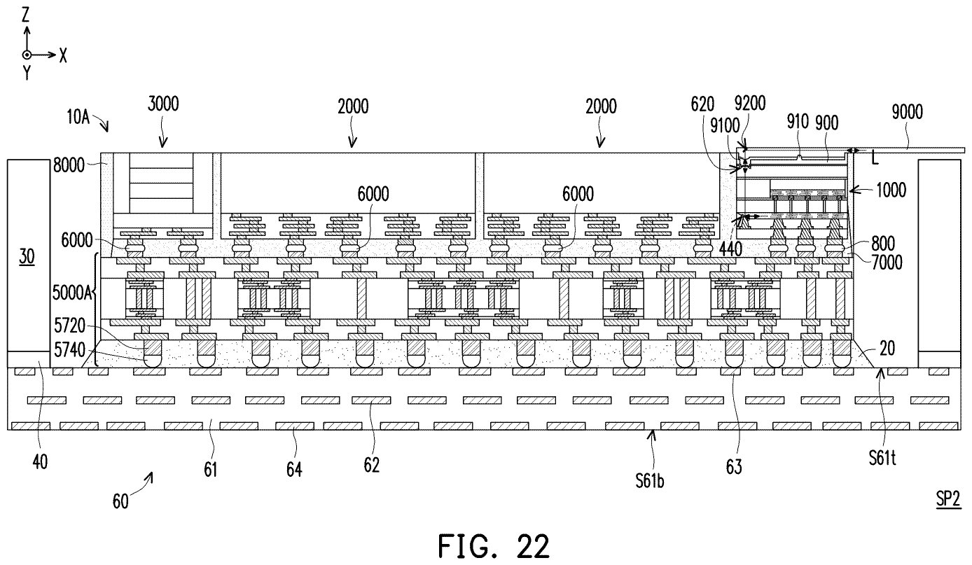

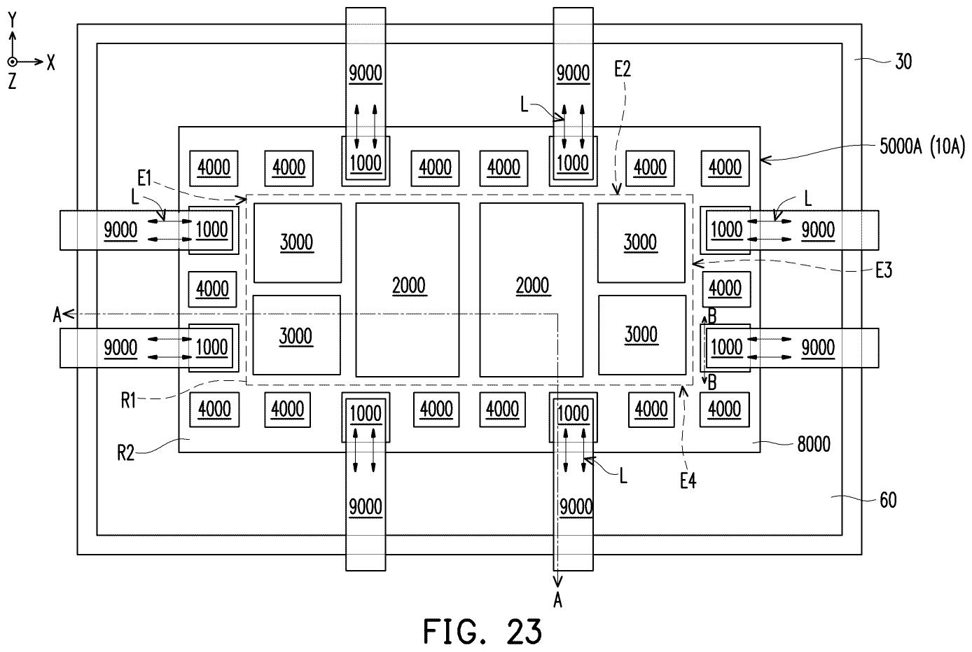

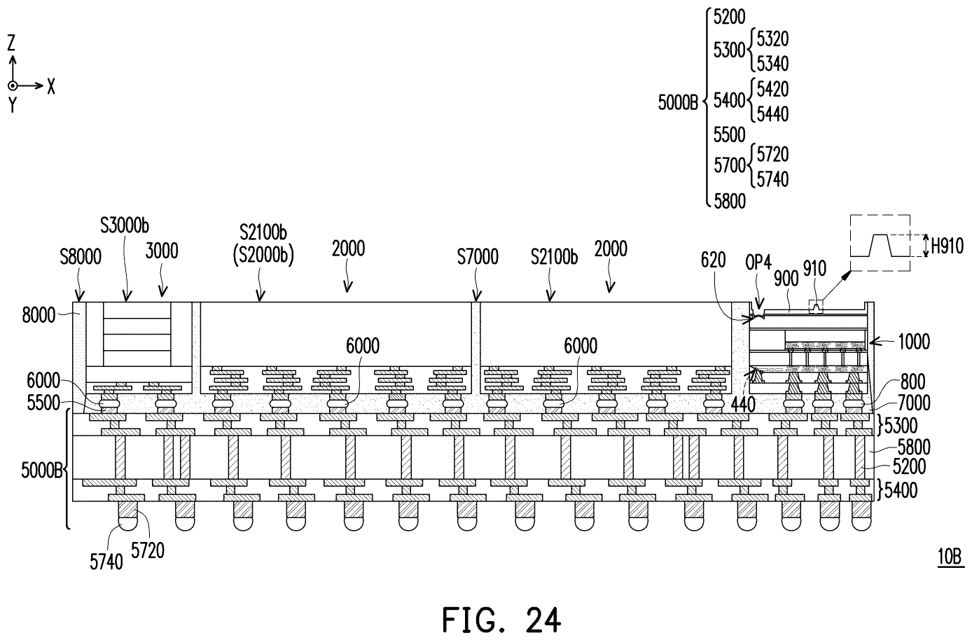

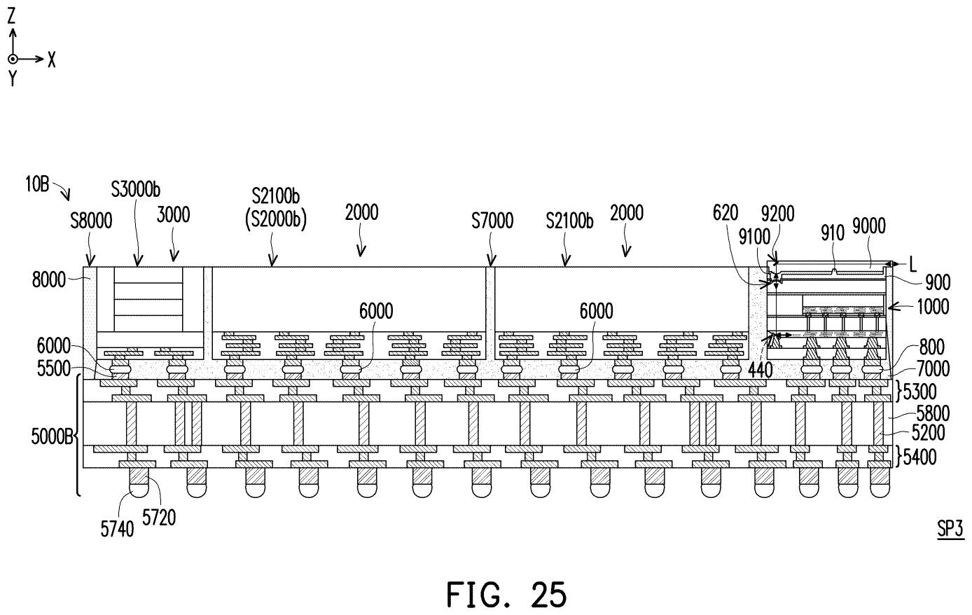

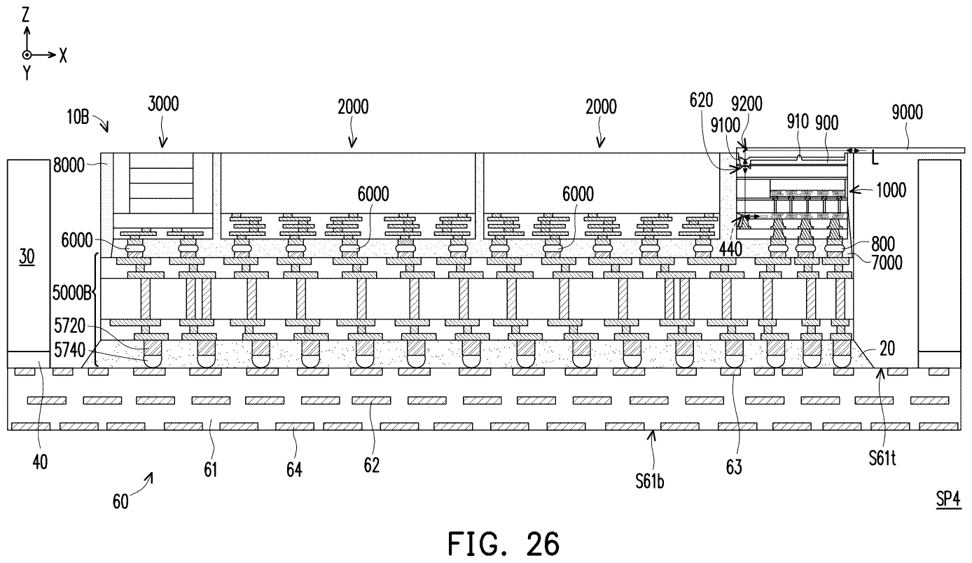

FIG. 1 through FIG. 21 are schematic cross-sectional or plane views of various stages in manufacturing a semiconductor package (e.g., SP1) in accordance with some embodiments of the disclosure, where the cross-sectional views of FIG. 1 through FIG. 13 are taken along a line BB depicted in the plane view of FIG. 21, and the cross-sectional views of FIG. 14 through FIG. 20 are taken along a line AA depicted in the plane view of FIG. 21. FIG. 22 and FIG. 23 are respectively schematic cross-sectional and plane views of a semiconductor package (e.g., SP2) in accordance with some alternative embodiments of the disclosure, where the cross-sectional view of FIG. 22 are taken along a line AA depicted in the plane view of FIG. 23. FIG. 24 and FIG. 25 are schematic cross-sectional views of a semiconductor package (e.g., SP3) in accordance with some embodiments of the disclosure. FIG. 26 is a schematic cross-sectional view of a semiconductor package (e.g., SP4) in accordance with some alternative embodiments of the disclosure.

Referring to FIG. 1, in some embodiments, a photonic wafer W including a plurality of photonic integrated circuit (PIC) components 100 therein is provided. The photonic integrated circuit components 100 are arranged into array and physically connected to one another. The photonic wafer W may include a plurality of device regions R0 each being configurated to identify the forming location of one optical die 1000. In each device region R0, one or more photonic integrated circuit components 100 may be included. For illustrative purposes, only one photonic integrated circuit component 100 included in each device region R0 is shown in FIG. 1, however the disclosure is not limited thereto; the number of the photonic integrated circuit component 100 in different device regions R0 may be the same or different and independently may be selected and designated based on the demand and design requirement. For example, the photonic integrated circuit components 100 are arranged in the form of a matrix (such as a N×N array or a N×M array, where N, M>0, N may or may not be equal to M) within at least one or each of the device regions R0. In some embodiments, the photonic integrated circuit components 100 each are be referred to as an optical integrated circuit component, a photonic die, a photonic chip, or a photonic integrated circuit.

Each one of the photonic integrated circuit components 100 respectively includes an electrical bonding portion 100a and at least one optical input/output portion 100b configured to transmit and receive optical signal, in some embodiments. The optical signal is, for example, pulsed light, light with continuous wave (CW), a combinations thereof, or the like. The electrical bonding portions 100a of the photonic integrated circuit components 100 may include semiconductor devices (e.g., active components such as transistors and so on, passive components such as capacitors, resistors, inductors, and so on, or combinations thereof), wirings, or conductors for electrical connection. The optical input/output portions 100b of the photonic integrated circuit components 100 may include semiconductor devices and optical devices for processing, receiving, and/or transmitting the optical signal. For example, the semiconductor devices formed in the optical input/output portions 100b may include transistors, capacitors, photodiodes or the combination thereof, and the optical devices formed in the optical input/output portions 100b may include one or more modulators (e.g., 180 in FIG. 1), one or more waveguides (e.g., 170 in FIG. 1), and one or more edge couplers (e.g., 160 in FIG. 1). In addition to or alternatively, the optical devices formed in the optical input/output portions 100b may further include input-output (I/O) couplers, filters, reflector, lasers, detectors (or saying photodetectors), splitters, converters, switches, or the combination thereof. For example, light-to-electrical conversion devices (e.g., photo-diodes) and/or electrical-to-light conversion devices (e.g., light emitting didoes, lamps, or the like) may be built inside the photonic integrated circuit components 100. Alternatively, light-to-electrical conversion devices (e.g., photo-diodes) and/or electrical-to-light conversion devices (e.g., light emitting didoes, lamps, or the like) may be built external to and attached to the photonic integrated circuit components 100. The edge coupler(s) (e.g., 160) allows optical signals and/or optical power to be transferred between the waveguide(s) (e.g., 170) and a photonic component (e.g., an optical fiber). The modulator(s) (e.g., 180) may be optically coupled to the waveguide(s) (e.g., 170) to receive electrical signals and generate corresponding optical signals within the waveguide(s) (e.g., 170) by modulating optical power within the waveguide(s) (e.g., 170). For example, the photodetector (not shown) may be optically coupled to the waveguide(s) (e.g., 170) to detect optical signals within the waveguide(s) and generate electrical signals corresponding to the optical signals.

As shown in FIG. 1, for example, the photonic wafer W may include an illustrated top surface (not labeled) and an illustrated bottom surface (not labeled) opposite to the illustrated top surface along a direction Z, wherein the electrical bonding portions 100a and the optical input/output portions 100b are located at the illustrated bottom surface of the photonic wafer W, where the electrical bonding portions 100a and the optical input/output portions 100b are disposed next to each other along a direction X or/and a direction Y. The directions X, Y, and Z may be different. The direction Z is perpendicular to the direction X and the direction Y, and the direction X is perpendicular to the direction Y, for example.

The photonic wafer W may include a semiconductor substrate 110 having a plurality of semiconductor devices and optical devices formed therein and/or thereon, a plurality of through vias 120 penetrating through the semiconductor substrate 110, an interconnection structure 130 disposed on a surface (e.g., S110b) of the semiconductor substrate 110 and electrically connected to the through vias 120, a dielectric layer 140 disposed on a surface (e.g., S110t) of the semiconductor substrate 110 and a plurality of conductive vias 150 disposed on the semiconductor substrate 110 and electrically connected to the through vias 120, where the conductive vias 150 are laterally covered by the dielectric layer 140. The conductive vias 150 are embedded in the dielectric layer 140 and exposed by a surface of the dielectric layer 140, for example. The conductive vias 150 are electrically connected to the semiconductor substrate 110 (e.g., the semiconductor devices and optical devices formed therein and/or thereon) through the through vias 120 and the interconnection structure 130. As shown in FIG. 1, the surface S110b may be opposite to the surface S110t along the direction Z.

The semiconductor substrate 110 may include a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Or, the semiconductor substrate 110 may include a dielectric substrate, or a substrate formed of other semiconductor materials. Other substrates, such as multi-layered or gradient substrates, may also be used.

The through vias 120 are electrically connected to the conductive vias 150 and extend downward into the semiconductor substrate 110 so to penetrate the semiconductor substrate 110 and electrically coupled to the interconnection structure 130, for example. In some embodiments, each of the through vias 120 is laterally covered by a barrier liner (not shown). For example, the barrier liners are formed between the through vias 120 and the semiconductor substrate 110. The barrier liners may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the barrier liners and the semiconductor substrate 110. The through vias 120, the barrier liners, and the optional dielectric liner may be formed by, but not limited to, forming a plurality of recesses in the semiconductor substrate 110; respectively depositing a dielectric material, a barrier material, and a conductive material (e.g., copper, tungsten, aluminum, silver, combinations thereof, or the like) in the recesses; and removing excess materials on the semiconductor substrate 110. For example, the recesses of the semiconductor substrate 110 are lined with the optional dielectric liner so as to laterally separate the barrier liners lining sidewalls of the through vias 120 from the semiconductor substrate 110. In some embodiments, the through vias 120 are formed by using a via-first approach, which are formed prior to the formation of the interconnection structure 130. Alternatively, the through vias 120 may be formed by using a via-last approach, and may be formed after the formation of the interconnection structure 130. The barrier liners and/or the additional dielectric liners may be omitted. The through vias 120 may be referred to as through-substrate-vias (TIVs) or through-silicon-vias if the semiconductor substrate 110 is made of silicon.

The interconnection structure 130 may include a dielectric structure 132 having one or more inter-dielectric layers and one or more patterned conductive layers 134 embedded in the dielectric structure 132 for providing routing function to the semiconductor devices and optical devices formed in and/or on the semiconductor substrate 110. In one embodiment, more inter-dielectric layers of the dielectric structure 132 and one or more patterned conductive layers 134 are stacked alternately along the direction Z. For example, the inter-dielectric layers of the dielectric structure 132 may be silicon oxide layers, silicon nitride layers, silicon oxynitride layers, or dielectric layers formed by other suitable dielectric materials, and the inter-dielectric layers may be formed by deposition or the like. For example, the patterned conductive layers 134 may be patterned copper layers or other suitable patterned metal layers, and the patterned conductive layers may be formed by electroplating or deposition. However, the disclosure is not limited thereto. The numbers of the layers of the inter-dielectric layers of the dielectric structure 132 and the patterned conductive layers 134 may be selected and designated based on the demand and/or design requirements, and is not specifically limited to the disclosure. The interconnection structure 130 may be referred to as an interconnection, an interconnect structure, an interconnect, or a routing structure. In some embodiments, the one or more edge couplers 160, the one or more waveguides 170 and the one or more modulators 180 of the optical input/output portions 100b are formed in and embedded inside the interconnection structure 130 within the optical input/output portions 100b of the photonic wafer W, as shown in FIG. 1.

The dielectric layer 140 may be formed by depositing a dielectric material layer on the semiconductor substrate 110 and patterning the dielectric material layer to form a plurality of openings (not labeled) in the dielectric material layer. The openings formed in the dielectric layer 140 expose the through vias 120 and portions of the semiconductor substrate 110. After the dielectric layer 140 is patterned, the conductive vias 150 may be formed by depositing a conductive material layer on the dielectric layer 140, the through vias 120 and the portions of the semiconductor substrate 110 exposed by the openings of the dielectric layer 140 and removing the excess materials on the dielectric layer 140 so to form the conductive vias 150 in the openings formed in the dielectric layer 140. The conductive vias 150 may be made of metal or metal alloy, and the dielectric layer 140 may be made of a dielectric material. For example, the material of the conductive vias 150 is copper (Cu) or other suitable metallic material while the material of the dielectric layer 140 is silicon oxide (SiOx, where x>0), silicon nitride (SiNx, where x>0), silicon oxynitride (SiOxNy, where x>0 and y>0) or other suitable dielectric material. The removing process may include a polishing process, such as a mechanical grinding process, a chemical mechanical polishing (CMP) process, an etching process, or a combination thereof. As shown in FIG. 1, for example, illustrated top surfaces of the conductive vias 150 and illustrated top surface of the dielectric layer 140 are substantially at the same level so as to provide an appropriate surface for bonding (e.g., a fusion bonding such as a metal-to-metal bonding and a dielectric-to-dielectric bonding). After the removing process, a cleaning step may be optionally performed, for example to clean and remove the residue generated from the removing process. However, the disclosure is not limited thereto, and the removing process may be performed through any other suitable method. In some embodiments, the dielectric layer 140 and the conductive vias 150 may together be referred to as a bonding layer or bonding structure, in the photonic integrated circuit components 100 of the disclosure.

Continued on FIG. 1, in some embodiments, a plurality of electric integrated circuit (EIC) components 200 are provided. Each one of the electric integrated circuit components 200 may respectively include a semiconductor substrate 210 having a plurality of semiconductor devices formed therein, an interconnection structure 220 disposed on a surface (e.g., S210b) of the semiconductor substrate 210, a dielectric layer 230 disposed over the interconnection structure 220, and a plurality of conductive vias 240 disposed over the interconnection structure 220 and electrically coupled to the interconnection structure 220, where the conductive vias 240 are laterally covered by the dielectric layer 230. The conductive vias 240 are embedded in the dielectric layer 230 and exposed by a surface of the dielectric layer 230, for example. The conductive vias 240 are electrically connected to the semiconductor substrate 210 (e.g., the semiconductor devices formed therein and/or thereon) through the interconnection structure 220. As shown in FIG. 1, the surface S210b may be opposite to a surface S210t of the semiconductor substrate 210 along the direction Z. The semiconductor devices formed in the semiconductor substrate 210 may active devices, passive devices, or a combination thereof. The devices may include integrated circuits devices. The semiconductor devices formed in the semiconductor substrate 210 may include transistors, capacitors, resistors, diodes, photodiodes, fuse devices, jumpers, inductors, or other similar devices. The functions of the semiconductor devices formed in the semiconductor substrate 210 may include memory, processors, sensors, amplifiers, power distribution, input/output circuitry, or the like. The semiconductor devices formed in the semiconductor substrate 210 each may be referred to as a semiconductor component.

As shown in FIG. 1, for example, illustrated top surfaces of the conductive vias 240 and an illustrated top surface of the dielectric layer 230 are substantially at the same level so as to provide an appropriate surface for bonding (e.g., a fusion bonding such as a metal-to-metal bonding and a dielectric-to-dielectric bonding). In some embodiments, the material of the conductive vias 240 may be copper (Cu) or other suitable metallic material while the material of the dielectric layer 230 may be silicon oxide (SiOx, where x>0), silicon nitride (SiNx, where x>0), silicon oxynitride (SiOxNy, where x>0 and y>0) or other suitable dielectric material. In some embodiments, the electric integrated circuit components 200 each are be referred to as a logic integrated circuit component, a logic or electric die, a logic or electric chip, a logic or electric integrated circuit to process the electric signal transmitted from the photonic integrated circuit components 100. The details, formations and materials of the semiconductor substrate 210, the interconnection structure 220, the dielectric layer 230 and the conductive vias 240 are similar to or substantially identical to the details, formations and materials of the first semiconductor substrate 110, the interconnection structure 130, the dielectric layer 140, and the conductive vias 150 previously discussed, and thus are not repeated herein for brevity. The interconnection structure 230 may be referred to as an interconnection, an interconnect structure, an interconnect, or a routing structure. In some embodiments, the dielectric layer 230 and the conductive vias 240 may together be referred to as a bonding layer or bonding structure, in the electric integrated circuit components 200 of the disclosure.

The electric integrated circuit components 200 may be picked-up and placed onto the illustrated top surface of the photonic wafer W such that the illustrated top surface of the photonic wafer W is in contact with an illustrated bottom surface of the electric integrated circuit components 200, and the conductive vias 240 of the electric integrated circuit components 200 are substantially aligned and in contact with the conductive vias 150 of the photonic integrated circuit components 100 included in the photonic wafer W. The electric integrated circuit components 200 are picked-up and placed to cover the electrical bonding portions 100a of photonic integrated circuit components 100, and the optical input/output portions 100b of the photonic integrated circuit components 100 are not covered by the electric integrated circuit components 200.

The electric integrated circuit components 200 placed on the photonic wafer W may be arranged in array. For example, the electric integrated circuit components 200 are arranged in the form of a matrix (such as a N′×N′ array or a N′×M′ array, where N′, M′>0, N′ may or may not be equal to M′) within at least one or each of photonic integrated circuit components 100 inside at least one or each of the device regions R0. The disclosure is not specifically limited as long as the electric integrated circuit components 200 are offset from the optical input/output portions 100b of the photonic integrated circuit components 100 in a vertical projection on the photonic wafer W along the direction Z. For example, in each of the device regions R0, the photonic integrated circuit components 100 and the electric integrated circuit components 200 are arranged in a one-to-one configuration. However, the disclosure is not limited thereto; alternatively, in each of the device regions R0, the photonic integrated circuit components 100 and the electric integrated circuit components 200 are arranged in a one-to-multiple configuration, such as 1-to-2 configuration, 1 to-3 configuration, 1-to-4 configuration, or so on.

The electric integrated circuit components 200 may be mounted to the photonic integrated circuit components 100 by a fusion bonding. In some embodiments, to facilitate the chip-to-wafer (CoW) fusion bonding between the electric integrated circuit components 200 and the photonic wafer W, surface preparation for bonding surfaces (i.e., the illustrated top surface of the photonic wafer W and the illustrated bottom surfaces of the electric integrated circuit components 200) may be performed. The surface preparation may include surface cleaning and activation, for example. Surface cleaning may be performed on the illustrated top surface of the photonic wafer W and the illustrated bottom surfaces of the electric integrated circuit components 200 so as to remove particles on the illustrated top surfaces of the conductive vias 150, the illustrated top surface of the dielectric layer 140, the illustrated bottom surfaces of the conductive vias 240 and the illustrated bottom surface of the dielectric layer 230. The illustrated top surface of the photonic wafer W and the illustrated bottom surfaces of the electric integrated circuit components 200 may be cleaned by wet cleaning, for example. Not only particles are removed, but also native oxide formed on the illustrated top surfaces of the conductive vias 150 and the illustrated bottom surfaces of the conductive vias 240 may be removed. The native oxide formed on the illustrated top surfaces of the conductive vias 150 and the illustrated bottom surfaces of the conductive vias 240 may be removed by chemicals used in the wet cleaning, for example.

After cleaning the illustrated top surface of the photonic wafer W and the illustrated bottom surfaces of the electric integrated circuit components 200, activation of the illustrated top surface of the dielectric layer 140 and the illustrated bottom surface of the dielectric layer 230 may be performed for development of high bonding strength. In some embodiments, plasma activation may be performed to treat the illustrated top surface of the dielectric layer 140 and the illustrated bottom surface of the dielectric layer 230. When the activated top surface of the dielectric layer 140 is in contact with the activated bottom surface of the dielectric layer 230, the dielectric layer 140 of the photonic wafer W and the dielectric layer 230 of the electric integrated circuit components 200 are pre-bonded. In other words, the photonic wafer W and the electric integrated circuit components 200 are pre-bonded through the pre-bonding of the dielectric layer 140 and the dielectric layer 230. After the dielectric layer 140 and the dielectric layer 230 are pre-bonded, the conductive vias 150 are in contact with and electrically connected to the conductive vias 240.

After pre-bonding the electric integrated circuit components 200 onto the photonic wafer W, the bonding of the electric integrated circuit components 200 and the photonic wafer W is performed. The bonding of the electric integrated circuit components 200 and the photonic wafer W may include a treatment for dielectric bonding and a thermal annealing for conductor bonding. In some embodiments, the treatment for dielectric bonding is performed to strengthen the bonding between the dielectric layer 140 and the dielectric layer 230. For example, the treatment for dielectric bonding may be performed at temperature ranging from about 100 Celsius degrees to about 150 Celsius degrees. For example, the dielectric bonding between the dielectric layer 140 and the dielectric layer 230 may be oxide-to-oxide bonding, oxide-to-nitride bonding or nitride-to-nitride bonding. After performing the treatment for dielectric bonding, the thermal annealing for conductor bonding is performed to facilitate the bonding between the conductive vias 150 and the conductive vias 240.

For example, the thermal annealing for conductor bonding may be performed at temperature ranging from about 300 Celsius degrees to about 400 Celsius degrees. The process temperature of the thermal annealing for conductor bonding is higher than that of the treatment for dielectric bonding. After performing the thermal annealing for conductor bonding, the dielectric layer 140 is bonded to the dielectric layer 230 and the conductive vias 150 are bonded to the conductive vias 240. In some embodiments, the conductive vias 150 may be connecting vias (e.g., copper vias), connecting or conductive pads (e.g., copper pads) or the combinations thereof while the conductive vias 240 may be connecting vias (e.g., copper vias), connecting or conductive pads (e.g., copper pads) or the combinations thereof. For example, the conductor bonding between the conductive vias 150 and the conductive vias 240 may be via-to-via bonding, pad-to-pad bonding or via-to-pad bonding. After performing the hybrid bonding of the electric integrated circuit components 200 and the photonic wafer W (e.g., the photonic integrated circuit components 100), the interconnection structure 130 and the interconnection structure 220 are electrically connected to each other through the conductive vias 150 and the conductive vias 240. The conductor bonding between the conductive vias 150 and the conductive vias 240 may be Cu-to-Cu bonding.

Alternatively, the electric integrated circuit components 200 may be mounted to the photonic integrated circuit components 100 by flip-chip bonding. In some embodiments, to facilitate the chip-to-wafer flip-chip bonding between the electric integrated circuit components 200 and the photonic wafer W, solder regions are further provided between the conductive vias 150 of the photonic integrated circuit components 100 and the conductive vias 240 of the electric integrated circuit components 200 to form solder joints for electrically connecting therebetween. For example, the conductor bonding between the conductive vias 150 and the conductive vias 240 may be via-to-solder joint-to-via bonding, pad-to-solder joint-to-pad bonding or via-to-solder joint-to-pad bonding. The dielectric layer 140 may be free from (e.g., spaced apart from) the dielectric layer 230. In the case, there is no dielectric bonding between the dielectric layer 140 and the dielectric layer 230. In the embodiments of which flip-chip bonding is employed, an underfill (not shown) may be optionally formed to fill the gaps between the electric integrated circuit components 200 and the photonic wafer W and cover sidewalls of the solder joints. Owing to the underfill, the bonding strength is enhanced, thereby improving the reliability of electrical connections between the electric integrated circuit components 200 and the photonic wafer W. The underfill may be any acceptable material, such as a polymer, epoxy, molding underfill, or the like, for example. The underfill may be formed by underfill dispensing or any other suitable method.

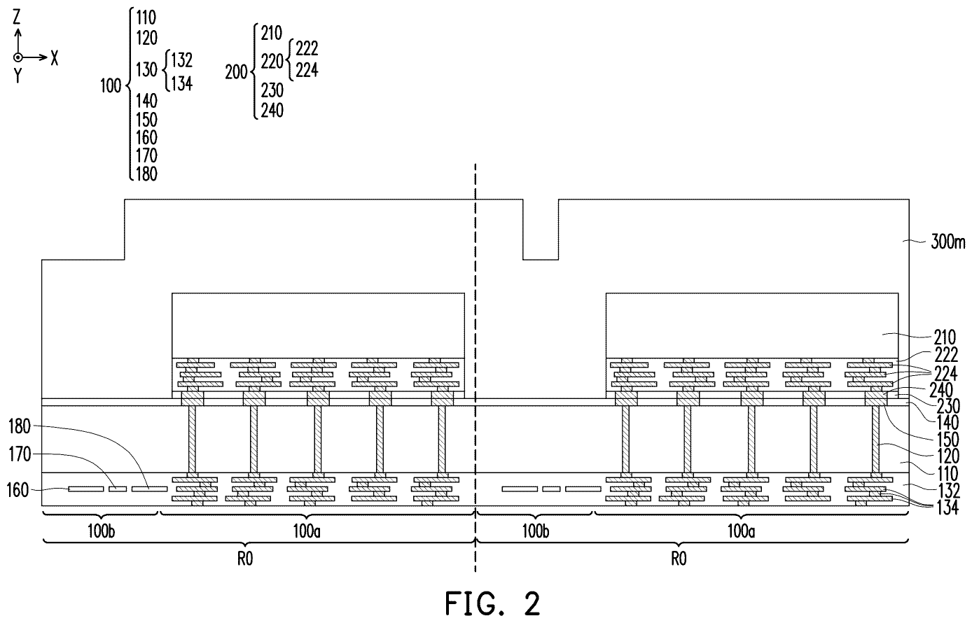

Referring to FIG. 2, in some embodiments, after performing the bonding of the electric integrated circuit components 200 and the photonic wafer W, an insulating material 300m is formed to cover the optical input/output portions 100b of the photonic wafer W and encapsulate the electric integrated circuit components 200. The maximum thickness of the insulating material 300m may be greater than the thickness of the electric integrated circuit components 200. In some embodiments, the insulating material 300m may be conformally formed by chemical vapor deposition (CVD), or other suitable deposition processes. Furthermore, the insulating material 300m is optically transparent to the optical signal to be processed by the optical input/output portions 100b of the photonic integrated circuit components 100.

In some embodiments, as shown in FIG. 2, the insulating material 300m may be a single-layered structure, and the material of the insulating material 300m may include silicon oxide, silicon nitride, and/or tetraethoxysilane (TEOS). In some alternative embodiments, the insulating material 300m may be a multi-layered structure and include a plurality of stacked dielectric layers in form of conformal layer, where the plurality of stacked dielectric layers of the multi-layered insulating material 300m are optically transparent to the optical signal to be processed by the optical input/output portions 100b and are stacked along the direction Z.

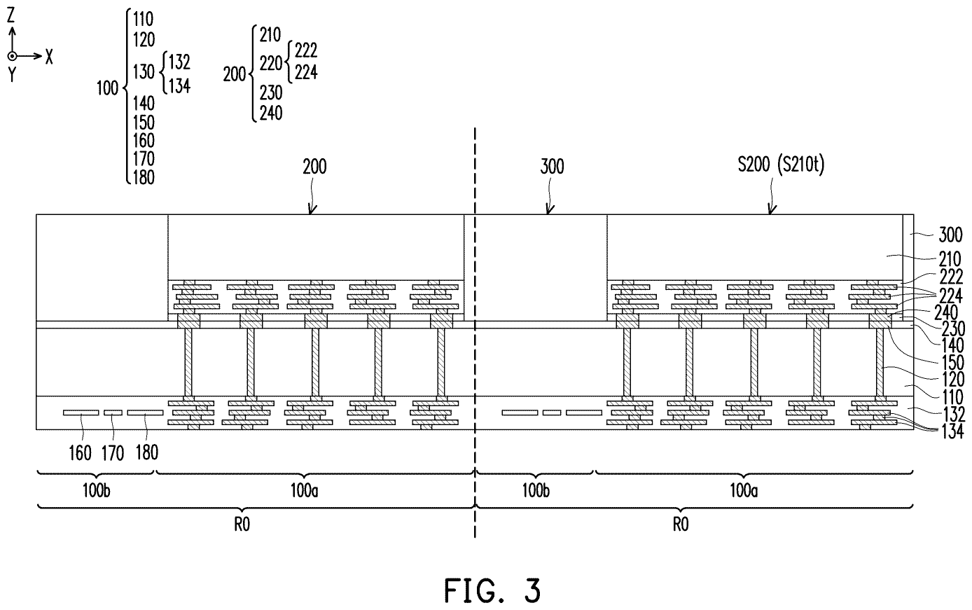

Referring to FIG. 3, in some embodiments, a grinding or polishing process is performed on the insulating material 300m to form an insulating encapsulation 300 exposing the electric integrated circuit components 200 (e.g., an illustrated top surface S200 (e.g., S210t)). For example, in the grinding or polishing process, the insulating material 300m is partially removed until the illustrated top surface S200 of the electric integrated circuit components 200 are exposed by an insulating encapsulation 300. The insulating material 300m and the electric integrated circuit components 200 may be partially removed by a CMP process, a mechanical grinding process, an etching process, a combination thereof, or other suitable removal processes. After performing the grinding or polishing process, the optical input/output portions 100b of the photonic integrated circuit components 100 are covered by the insulating encapsulation 300, and the electric integrated circuit components 200 are laterally encapsulated by the insulating encapsulation 300, as shown in FIG. 3, for example. Furthermore, the insulating encapsulation 300 physically contacts the sidewalls of the electric integrated circuit components 200. In some embodiments, a surface S300 of the insulating encapsulation 300 is substantially levelled with the illustrated top surface S200 of the electric integrated circuit components 200. For example, the surface S300 of the insulating encapsulation 300 is substantially coplanar to the illustrated top surface S200 of the electric integrated circuit components 200. During the grinding or polishing process, the electric integrated circuit components 200 may be partially removed, as well. After the grinding or polishing process, a cleaning step may be optionally performed, for example to clean and remove the residue generated from the grinding or polishing process. However, the disclosure is not limited thereto, and the grinding or polishing process may be performed through any other suitable method.

In some embodiments, as shown in FIG. 3, the insulating encapsulation 300 is a single-layered structure, and the material of the insulating encapsulation 300 includes silicon oxide, silicon nitride, and/or tetraethoxysilane (TEOS). In some alternative embodiments, the insulating encapsulation 300 may be a multi-layered structure and include a plurality of stacked dielectric layers, where the plurality of stacked dielectric layers of the multi-layered insulating encapsulation 300 are optically transparent to the optical signal to be processed by the optical input/output portions 100b. Furthermore, the stacked dielectric layers may be formed from multiple layers of alternating dielectric materials (e.g., alternating silicon oxide/silicon nitride layers) with varying refractive index or thickness. The stacked dielectric layers of the multi-layered insulating encapsulation 300 may provide anti-reflection effect. The insulating encapsulation 300 may be referred to as an insulating encapsulant, a dielectric encapsulation, a dielectric encapsulant, an encapsulation, or an encapsulant.

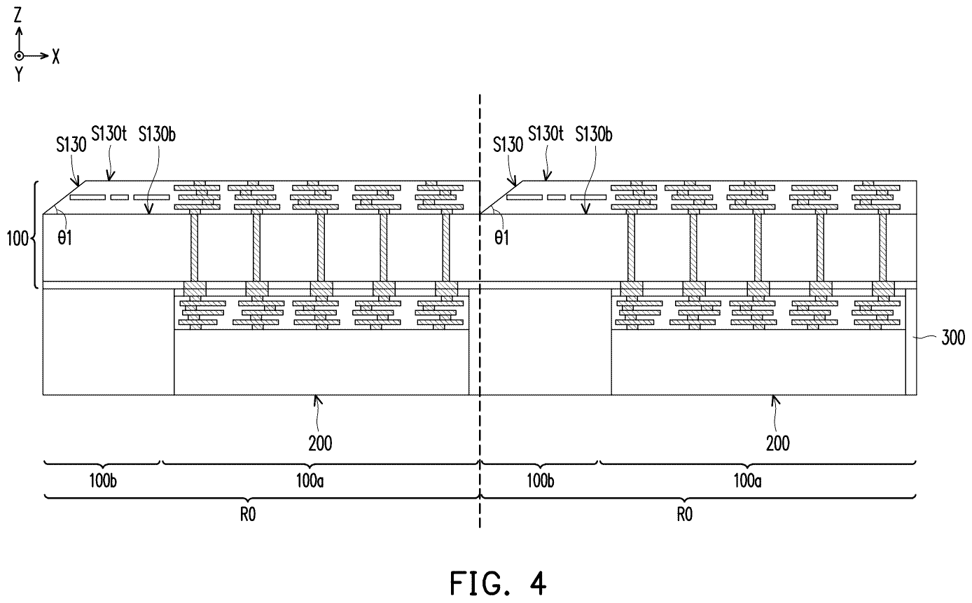

Referring to FIG. 4, in some embodiments, the whole structure depicted in FIG. 3 is flipped over (e.g., turned upside down), and the interconnection structures 130 of the photonic integrated circuit components 100 of the photonic wafer W are patterned to obtain surfaces S130 near the edge couplers 160 in the interconnection structures 130 of the photonic integrated circuit components 100. For example, in each of photonic integrated circuit components 100 of the photonic wafer W, an angle θ1 between the surface S130 and an illustrated bottom surface S130b is about 45 degrees. In such case, an angle between the surface S130 and an illustrated top surface S130t may about 45 degrees, as shown in FIG. 4. In some embodiments, a surface roughness (Rq) of the surface S130 is less than or substantially equal to about 15 Å (angstrom). For a non-limiting example, the surface roughness (Rq) of the surface S130 is approximately ranging from 5 Å to 15 Å. For another non-limiting example, the surface roughness (Rq) of the surface S130 is less than or substantially equal to about 5 Å. For example, the illustrated top surface S130t and the illustrated bottom surface S130b are opposite to each other along the direction Z. The patterning process may include photolithography (involving a grey-tone mask with a photoresist having 45 degrees surface) and etching processes (e.g., transferring the pattern of photoresist onto the interconnect structure 130). However, the disclosure is not limited thereto, and the patterning process may be performed through any other suitable method.

The whole structure depicted in FIG. 3 (e.g., the electric integrated circuit components 200 and the insulating encapsulation 300 thereof) may be placed onto a temporary carrier (not shown) to securely hold the whole structure depicted in FIG. 3 during the sequent processes. For example, the temporary carrier is a wafer-level carrier. In some embodiments, the wafer-level carrier is a glass carrier or any suitable carrier for carrying a semiconductor wafer or a reconstituted wafer (such as the whole structure depicted in FIG. 3) for the manufacturing method of the semiconductor package SP1. In some embodiments, the wafer-level carrier is coated with a debond layer (not shown). The material of the debond layer may be any material suitable for bonding and de-bonding the wafer-level carrier from the above layer(s) or any wafer(s) disposed thereon. In some embodiments, the debond layer includes a dielectric material layer made of a dielectric material including any suitable polymer-based dielectric material (such as benzocyclobutene (“BCB”), polybenzoxazole (“PBO”)). In an alternative embodiment, the debond layer includes a dielectric material layer made of an epoxy-based thermal-release material, which loses its adhesive property when heated, such as a light-to-heat-conversion (LTHC) release coating film. In a further alternative embodiment, the debond layer includes a dielectric material layer made of an ultra-violet (UV) glue, which loses its adhesive property when exposed to UV lights. The debond layer may be dispensed as a liquid and cured, or may be a laminate film laminated onto the wafer-level carrier, or may be the like. The top surface of the debond layer, which is opposite to a bottom surface contacting the wafer-level carrier, may be levelled and may have a high degree of coplanarity. The debond layer is, for example, a LTHC layer with good chemical resistance, and such layer enables room temperature de-bonding from the wafer-level carrier by applying laser irradiation, however the disclosure is not limited thereto. In the embodiments of which the wafer-level carrier and the debond layer are presented, the debond layer is sandwiched between the whole structure depicted in FIG. 3 and the wafer-level carrier. Alternatively, the temporary carrier may be a holding device. For example, the holding device includes an adhesive tape, a carrier film or a suction pad. The disclosure is not limited thereto. In the embodiments of which the holding device is employed, the whole structure depicted in FIG. 3 is disposed over and in physical contact with the holding device.

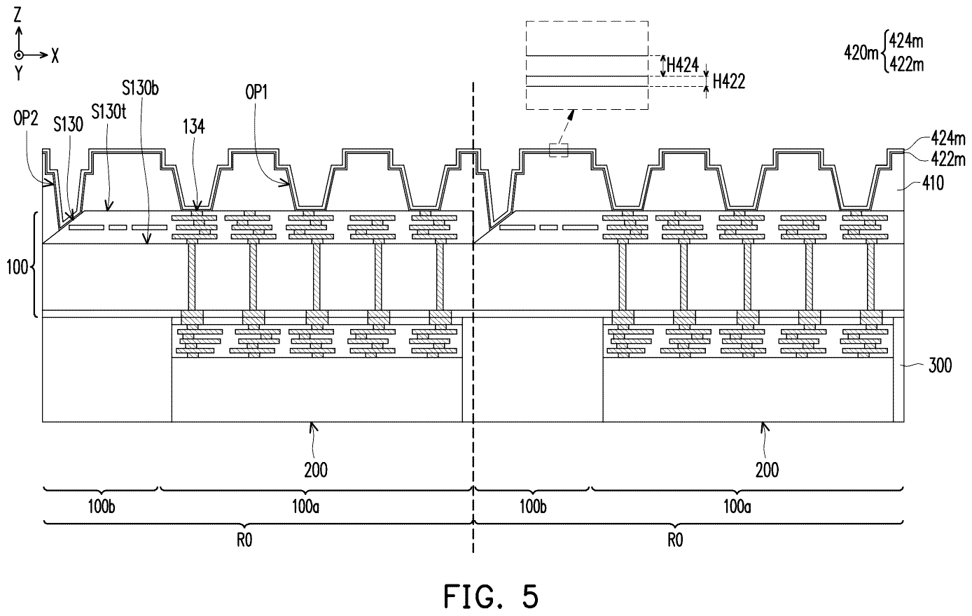

Referring to FIG. 5, in some embodiments, a dielectric layer 410 is formed on the illustrated top surface S130t of the interconnection structure 130, where the dielectric layer 410 has a plurality of openings OP1 exposing portions of the patterned conductive layers 134 embedded in the dielectric structure 132 of the interconnection structure 130 and a plurality of openings OP2 exposing the surfaces S130 of the interconnection structure 130. The formation and material of the dielectric layer 410 may be similar to or substantially identical to the formation and material of the dielectric layer 150 previously described in FIG. 1, and thus are not repeated herein for brevity. After forming the dielectric layer 410, a seed material layer 420m is disposed on the dielectric layer 410 and further extended into the openings OP1, OP2 to be in contact with the portions of the patterned conductive layers 134 and the surface S130 exposed by the dielectric layer 410. In some embodiments, the seed material layer 420m is conformally formed on the dielectric layer 410 and further extended into the openings OP1 to be in contact with the portions of the patterned conductive layers 134 embedded in the dielectric structure 132 of the interconnection structure 130 exposed by the dielectric layer 410 and the openings OP2 to be in contact with the surface S130 of the interconnection structure 130 exposed by the dielectric layer 410 in a form of multiple metal or metal alloy layers, where each of the multiple metal or metal alloy layers is a blanket layer of metal or metal alloy materials.

In some embodiments, as shown in FIG. 5, the seed material layer 420m includes a first seed material layer 422m and a second seed material layer 424m stacked on the first seed material layer 422m along the direction Z. As shown in FIG. 5, along the direction Z, a thickness H422 of the first seed material layer 422m may be less than a thickness H424 of the second seed material layer 424m. In some embodiments, the thickness H422 of the first seed material layer 422m approximately ranges from 200 Å to 1500 Å. In some embodiments, the thickness H424 of the second seed material layer 424m is greater than or substantially equal to 3000 Å. A material of the first seed material layer 422m may include titanium, titanium alloy or the like, and the first seed material layer 422m may be formed by deposition (such as physical vapor deposition (PVD)) or sputtering. A material of the second seed material layer 424m may include copper, copper alloy or the like, and the second seed material layer 424m may be formed by deposition (such as PVD) or sputtering. As shown in FIG. 5, in some embodiments, the seed material layer 420m lines sidewalls and bottoms of the openings OP1, OP2 formed in the dielectric layer 410 and further extends onto a surface of dielectric layer 410 opposing to the photonic wafer W, where the seed material layer 420m is in contact with (e.g., in physical contact with) the portions of the patterned conductive layers 134 embedded in the dielectric structure 132 of the interconnection structure 130 and the surface S130 of the interconnection structure 130 exposed by the dielectric layer 410.

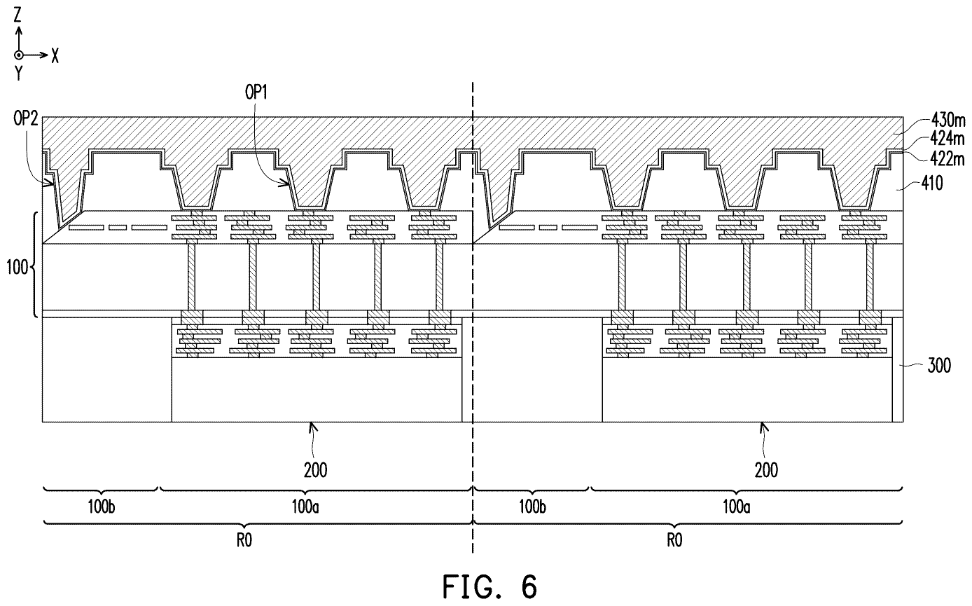

Referring to FIG. 6, in some embodiments, a conductive material 430m may be disposed on (e.g., in contact with) the seed layer material 420m. In some embodiments, the openings OP1 and OP2 are filled with the conductive materials 430m over the seed layer material 420m. In some embodiments, a material of the conductive material 430m includes a suitable conductive material, such as metal and/or metal alloy. For example, the conductive material 430m can be aluminum (Al), aluminum alloys, copper (Cu), copper alloys, or combinations thereof (e.g. AlCu), the like, or combinations thereof. In some embodiments, the conductive material 430m is formed by plating process or any other suitable method, which the plating process may include electroplating or electroless plating, or the like. In alternative embodiments, the conductive material 430m may be formed by deposition. The disclosure is not limited thereto.

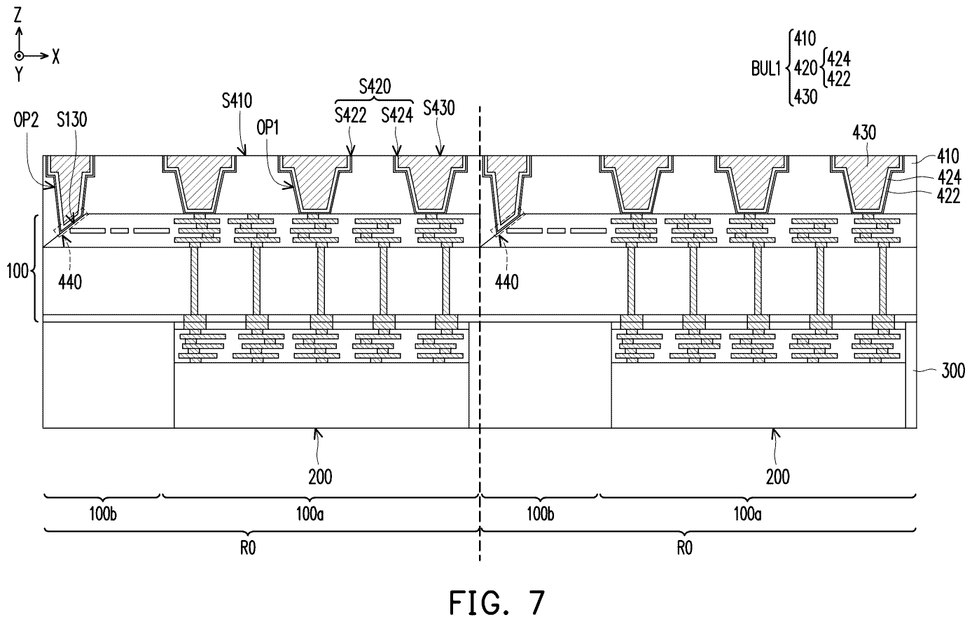

Referring to FIG. 6 and FIG. 7 together, in some embodiments, a planarization process is performed to remove excessive amounts of the conductive material 430m and the seed layer material 420m over a plane including an illustrated top surface (e.g. a surface S410) of the dielectric layer 410, thereby forming a seed layer 420 and a conductive feature 430 in the openings OP1 and OP2 of the dielectric layer 410. As shown in FIG. 7, a surface S430 of the conductive feature 430 and a surface S420 (including S422 and S424) of the seed layer 420 may be substantially leveled with the surface S410 of the dielectric layer 410. For example, the surface S430 of the conductive feature 430 and, the surface S420 of the seed layer 420 are substantially coplanar to the surface S410 of the dielectric layer 410. The planarization process may include a grinding process, CMP process, an etching process, the like, or combinations thereof. During the planarizing process, the dielectric layer 410 may also be planarized. After planarizing, a cleaning process may be optionally performed, for example to clean and remove the residue generated from the planarizing process. However, the disclosure is not limited thereto, and the planarizing process may be performed through any other suitable method.

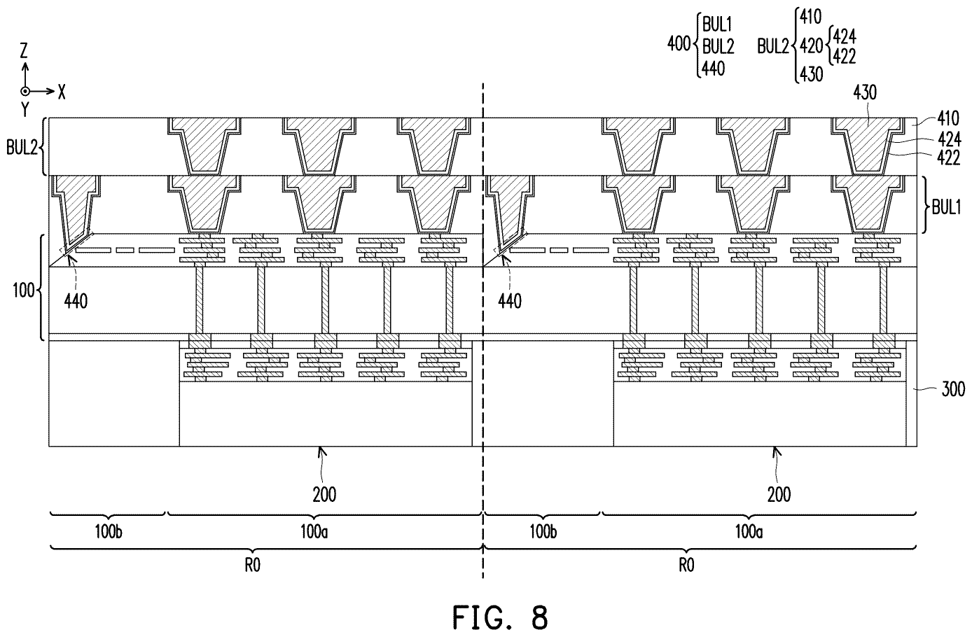

In some embodiments, the conductive feature 430 and the seed layer 420 formed in each opening OP1 are collectively referred to as a metallization structure, a metallization layer, a metallization pattern, a conductive structure, a conductive layer, a conductive pattern, a routing structure, a routing layer, a redistribution structure or a redistribution layer of a redistribution circuit structure (e.g., 400 in FIG. 8), and the dielectric layer 410 is referred to as a dielectric structure of the redistribution circuit structure (e.g., 400 in FIG. 8). The metallization structure (e.g., 420 and 430) and the dielectric structure (e.g., 410) may be considered as a build-up layer BUL1 of the redistribution circuit structure (e.g., 400 in FIG. 8). For example, the metallization structure penetrates through the dielectric structure and is in contact with the portions of the patterned conductive layers 134 embedded in dielectric structure 132 of the interconnection structure 130 and exposed from the dielectric structure (e.g., 410). That is, the metallization structure may be electrically connected to the photonic integrated circuit components 100 of the photonic wafer W and further be electrically connected to the electric integrated circuit components 200 through the respective photonic integrated circuit components 100.

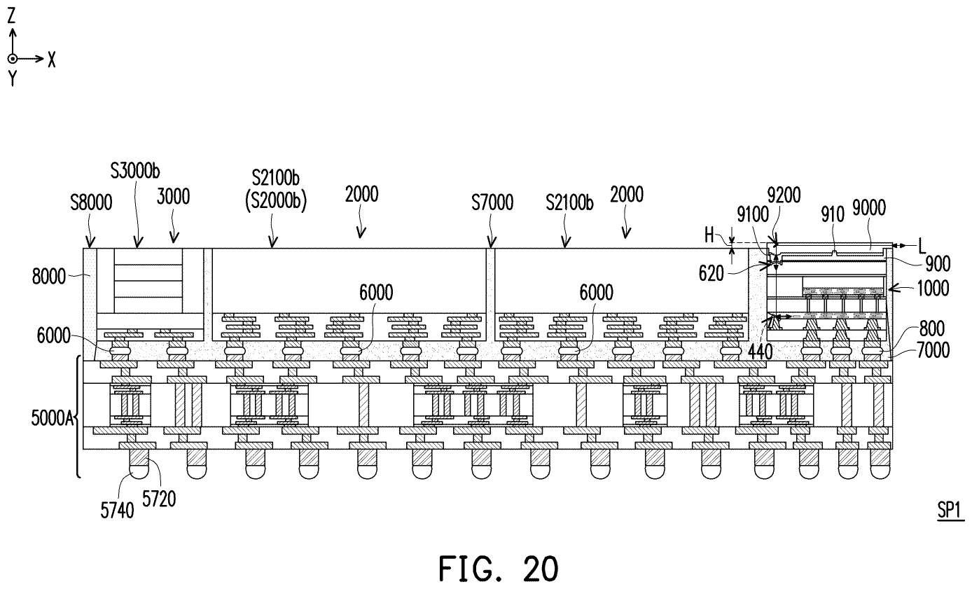

In addition, the conductive features 430 and the seed layers 420 formed in the openings OP2 are electrically isolated to the conductive features 430 and the seed layers 420 formed in the openings OP1. In some embodiments, the seed layers 420 formed in the openings OP2 are considered as reflectors 440 which being capable to reflect a vertical light into a horizontal light, where an angle between the plane the illustrated top surface S130t or the illustrated bottom surface 130b located at and the plane the seed layers 420 formed in the openings OP2 located at is about 45 degrees. The reflectors 440 may be referred to as reflecting structures, mirrors, or mirror structures, where the reflectors 440 is embedded to the redistribution circuit structure (e.g., 400 in FIG. 8) and posited at the optical path of an optical signal (e.g., L in FIG. 20 through FIG. 21) between the edge coupler 160 and the photonic component (e.g., an optical fiber, see 9000 in FIG. 20 through FIG. 21).

Referring to FIG. 8, in some embodiments, one or more build-up layers, through the processes of IG. 5 through FIG. 7, are optionally formed on the build-up layer BUL1 so to form the redistribution circuit structure 400 over the photonic wafer W, where the photonic wafer W is disposed between and electrically coupled to the electric integrated circuit components 200 and the redistribution circuit structure 400 and is also disposed between the insulating encapsulation 300 and the redistribution circuit structure 400. For example, only one build-up layer BUL2 is formed for illustrated purposes and simplicity, the disclosure is not limited thereto. The details, formations and material of the build-up layer BUL2 may be similar to or substantially identical to the details, formations and material of the build-up layer BUL1 previously described in FIG. 5 through FIG. 7, and thus are not repeated herein for brevity. The number of build-up layers included in the redistribution circuit structure 400 may be one, two, three, or more, which can be selected and designated based on the demand and the design requirements; the disclosure is not limited thereto.

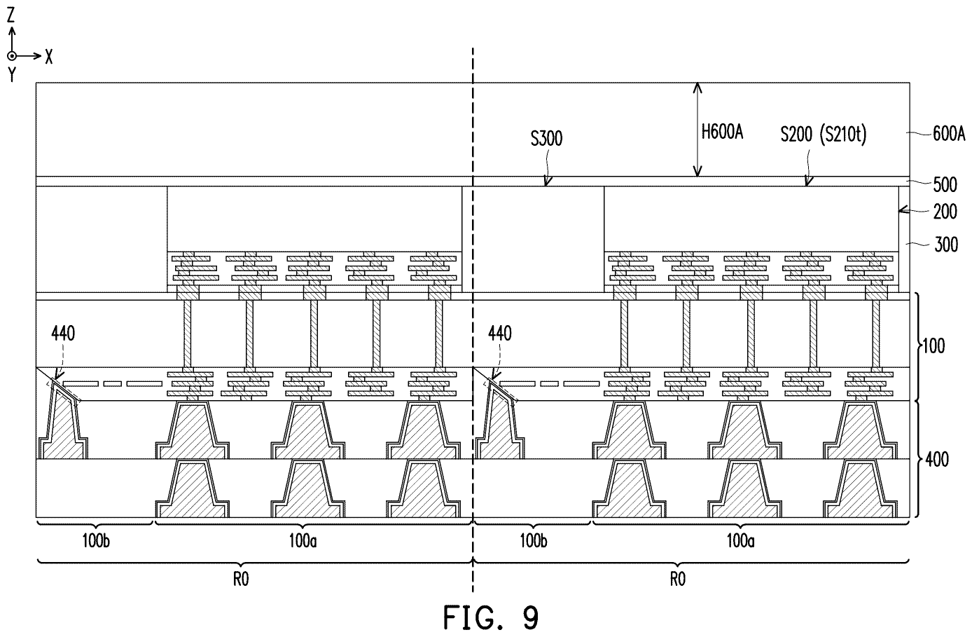

Referring to FIG. 9, in some embodiments, the whole structure depicted in FIG. 8 is flipped over (e.g., turned upside down), and an anti-reflection coating (ARC) layer 500 is conformally formed over the electric integrated circuit components 200 and the insulating encapsulation 300. For example, the ARC layer 500 is disposed on and in physical contact with the illustrated top surfaces S200 of the electric integrated circuit components 200 and the surface S300 of the insulating encapsulation 300. The ARC layer 500 may be made of a dielectric material, and may be formed by any suitable method, such as CVD or atomic layer deposition (ALD). A material of the ARC layer 500 may include silicon oxide such as SiO or SiO₂, silicon nitride, silicon oxynitride, or combinations thereof. For example, the ARC layer 500 includes a conformal layer of silicon nitride. The ARC layer 500 may have a thickness of about 300 nm to about 900 nm as measured along the direction Z, although other suitable thickness may alternatively be utilized. The ARC layer 500 may be referred to as an optical layer or film, or an anti-reflection layer or film.

Thereafter, a supporting structure 600A is provided and disposed on the ARC layer 500, as shown in FIG. 9, for example. The supporting structure 600A may be a semiconductor substrate, such as a bulk semiconductor substrate, a semiconductor-on-insulator (SOI) substrate, or the like, which may be doped (e.g., with a p-type or an n-type dopant) or undoped. The supporting structure 600A may be a wafer, such as a silicon wafer. Generally, an SOI substrate is a layer of a semiconductor material formed on an insulator layer. The insulator layer may be a buried oxide (BOX) layer, a silicon oxide layer, or the like. For example, the insulator layer is provided on a substrate, typically a silicon or glass substrate. Other substrates, such as a multilayered or gradient substrate may also be used. In some embodiments, the semiconductor material of the supporting structure 600A includes an elementary semiconductor (e.g., silicon or germanium in a crystalline, a polycrystalline, or an amorphous structure, etc.); a compound semiconductor (e.g., silicon carbide, gallium arsenide, gallium phosphide, indium phosphide, indium arsenide, and/or indium antimonide); an alloy semiconductor (e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP)); or combinations thereof. The supporting structure 600A may include a dielectric material. For example, the supporting structure 600A is a dielectric substrate, or include a dielectric layer on a semiconductor substrate. Acceptable dielectric materials for dielectric substrates may include oxides such as silicon oxide; nitrides such as silicon nitride; carbides such as silicon carbide; the like; or combinations thereof such as silicon oxynitride, silicon oxycarbide, silicon carbonitride, or the like. The disclosure is not specifically limited, as long as the supporting structure 600A is optically transparent to the targeted wavelength range of the optical signal to-be-transmitted and to-be-received by the optical input/output portion 100b underneath thereto.

In some embodiments, as shown in FIG. 9, the supporting structure 600A is formed of silicon, e.g., a silicon substrate. However, the disclosure is not limited thereto. In some embodiments, the supporting structure 600A is bonded to the ARC layer 500 by performing a thermal process to establish bonds (e.g., covalent bonds) between the supporting structure 600A and the ARC layer 500 (e.g., at the interface of the supporting structure 600A and the ARC layer 500). As shown in FIG. 9, The ARC layer 500 is disposed between the supporting structure 600A and the insulating encapsulation 300 and between the supporting structure 600A and the electric integrated circuit components 200, for example. The electric integrated circuit components 200 and the insulating encapsulation 300 are disposed between the ARC layer 500 and the photonic wafer W, in the case. Owing to the supporting structure 600A of silicon substrate, a low loss purpose during the manufacture is achieved.

Prior to forming the ARC layer 500 and after flipping over the whole structure depicted in FIG. 8, the debonding process is performed on the debond layer so to remove the temporary carrier and the debond layer, where the electric integrated circuit components 200 and the insulating encapsulation 300 are accessibly revealed. In some embodiments, after flipping over the whole structure depicted in FIG. 8 and prior to debonding the temporary carrier and the debond layer, the whole structure depicted in FIG. 8 (e.g., the redistribution circuit structure 400 thereof) may be placed onto another temporary carrier (not shown) coated with another debond layer disposed thereon to securely hold the whole structure depicted in FIG. 8 during the sequent processes. The details of the another temporary carrier and the another debond layer may be similar to or substantially identical to the details of the temporary carrier and the debond layer previously described in FIG. 4, and thus are not repeated herein. In the embodiments of which the wafer-level carrier and the debond layer are presented, the debond layer is sandwiched between the whole structure depicted in FIG. 8 and the wafer-level carrier. Alternatively, the another temporary carrier may be a holding device. In the embodiments of which the holding device is employed, the whole structure depicted in FIG. 8 is disposed over and in physical contact with the holding device. For example, the holding device includes an adhesive tape, a carrier film or a suction pad.

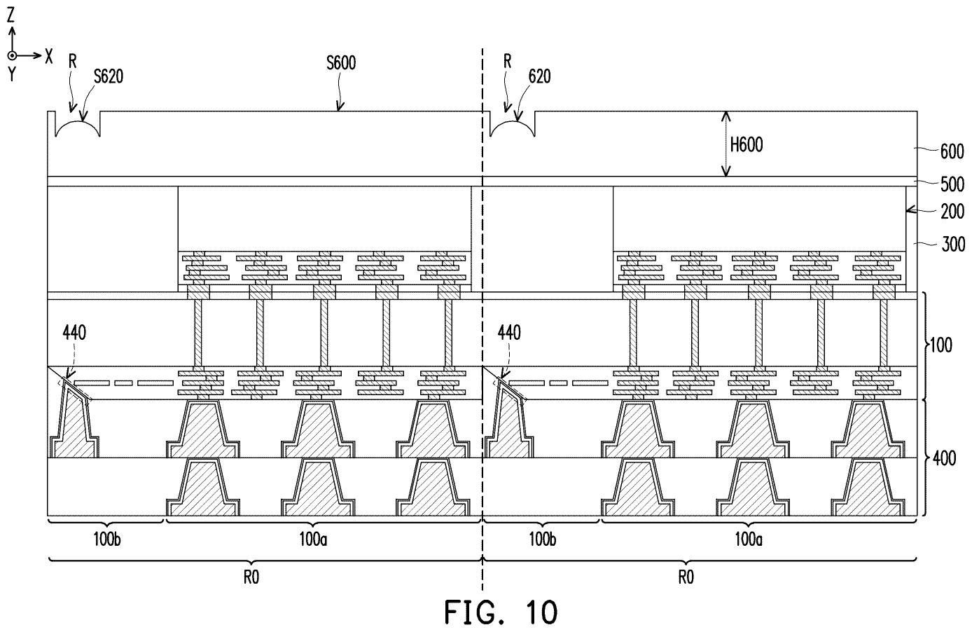

Referring to FIG. 10, in some embodiments, the supporting structure 600A is patterned to form a supporting structure 600 having a plurality of lens structures 620 formed thereon (e.g., on a surface S600). For example, the lens structures 620 are located at the surface S600 of the supporting structure 600, where an outermost point of a surface S620 of each lens structure 620 is below the surface S600 of the supporting structure 600 by a non-distance, as shown in FIG. 10. However, the disclosure is not limited thereto; the outermost point of the surface S620 of each lens structure 620 may be located at the same level where the surface S600 of the supporting structure 600 being located at. Alternatively, the outermost point of the surface S620 of each lens structure 620 is above the surface S600 of the supporting structure 600 by a non-zero distance. In some embodiments, the surfaces S620 are referred to as outermost surfaces of the lens structure 620, and the surface S600 is referred to as an outermost surface of the supporting structure 600. In some embodiments, the lens structures 620 and the supporting structure 600 are integrally formed, such as an integral piece. The thickness H600A of the supporting structure 600A of FIG. 9 may be less than a thickness H600 of the supporting structure 600 of FIG. 10. The patterning process may include photolithography (involving a grey-tone mask) and etching processes (e.g., transferring the pattern of photoresist onto the interconnect structure 130). However, the disclosure is not limited thereto, and the patterning process may be performed through any other suitable

In a non-limiting example, for one semiconductor structure SP1, the lens structures 620 formed in the supporting structure 600 and the optical input/output portions 100b of the photonic integrated circuit components 100 are in one-to-one configuration, such as one lens structure 620 per optical input/output portion 100b. In another non-limiting example, for one semiconductor structure SP1, the lens structures 620 formed in the supporting structure 600 may be arranged in array, where the lens structures 620 formed in the supporting structure 600 and the optical input/output portions 100b of the photonic integrated circuit components 100 are in multiple-to-one configuration, such as multiple lens structures 620 per optical input/output portion 100b. For example, the lens structures 620 are arranged in the form of a matrix (such as a N″×N″ array or a N″×M″ array, where N″, M″>0, N″ may or may not be equal to M″) within at least one or each of photonic integrated circuit components 100 inside at least one or each of the device regions R0. The disclosure is not specifically limited as long as the lens structures 620 are capable of being optically coupled to the optical input/output portions 100b of the photonic integrated circuit components 100 in the photonic wafer W. In some embodiments, in the top view, the lens structures 620 are arranged into a line, such as a 1×M″ array (M″>1) or N″×1 array (N″>1), not shown. In alternative embodiments, in the top view, the lens structures 620 arranged in immediately adjacent rows and/or columns are positioned in an alignment manner (e.g., an array form) on the X-Y plane, not shown. Alternatively, the lens structures 620 arranged in immediately adjacent rows and/or columns may be positioned in a staggered manner (e.g., a staggered form) on the X-Y plane, not shown. In further alternative embodiments, the lens structures 620 are arranged into a pre-determined pattern in a concentric manner, where the lens structures 620 are in a radial arrangement, not shown. The number of the lens structures 620 is specifically limited in the disclosure. Depending on the demand and design requirements, the number of the lens structures 620 may be one or more than one for each optical input/output portion 100b.

In some embodiments, positioning locations of the lens structures 620 correspond to (e.g., overlap with) positioning locations of the optical input/output portions 100b of the photonic integrated circuit components 100 in the vertical projection on the photonic wafer W along the direction Z. For example, the lens structures 620 are optically coupled to the optical input/output portions 100b of the photonic integrated circuit components 100 in the photonic wafer W. In some embodiments, the lens structures 620 are posited at the optical path of the optical signal (e.g., L in FIG. 20 through FIG. 21) between the edge coupler 160 and the photonic component (e.g., an optical fiber, see 9000 in FIG. 20 through FIG. 21), and are further optically coupled to the reflectors 440, respectively.

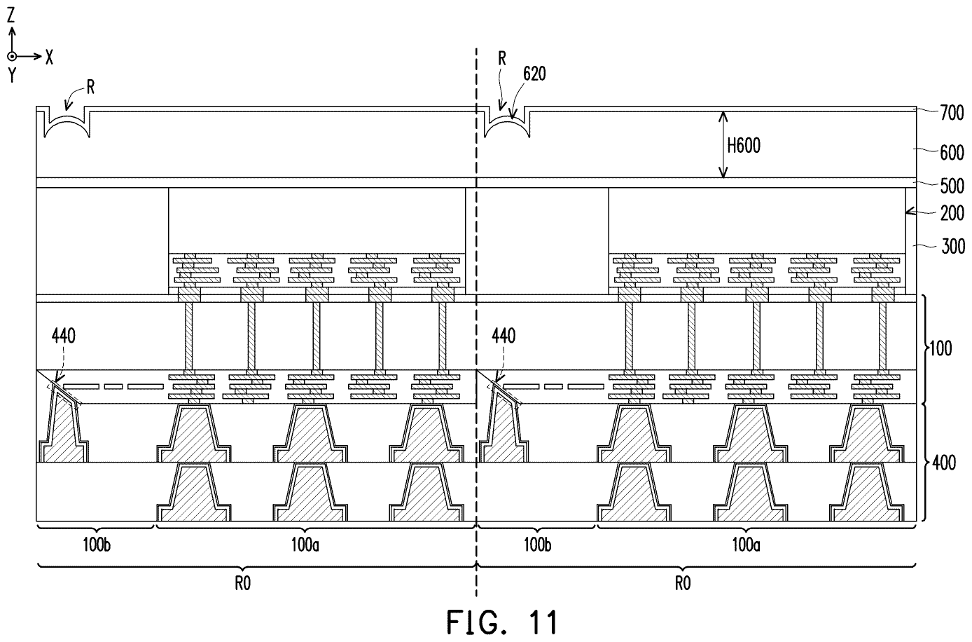

Referring to FIG. 11, in some embodiments, an ARC layer 700 is conformally formed over the lens structures 620 and the supporting structure 600. For example, the ARC layer 700 is disposed on and in physical contact with the surfaces S620 of the lens structures 620 and the surface S600 of the supporting structure 600. In the case, the ARC layer 700 extends into recesses R formed in the supporting structure 600 to line the sidewall and bottom surface of the recesses R. The ARC layer 700 may be made of a dielectric material, and may be formed by any suitable method, such as CVD or ALD. A material of the ARC layer 700 may include silicon oxide such as SiO or SiO₂, silicon nitride, silicon oxynitride, or combinations thereof. For example, the ARC layer 700 includes a conformal layer of silicon nitride. The material of the ARC layer 700 is substantially the same to the material of the ARC layer 600, in one embodiment. Alternatively, the material of the ARC layer 700 may be different from the material of the ARC layer 600. The ARC layer 700 may have a thickness of about 300nm to about 900nm as measured along the direction Z, although other suitable thickness may alternatively be utilized. The thickness of the ARC layer 700 is substantially the same to the thickness of the ARC layer 600, in one embodiment. Alternatively, the thickness of the ARC layer 700 may be different from the thickness of the ARC layer 600. The disclosure is not limited thereto. The ARC layer 700 may be referred to as an optical layer or film, or an anti-reflection layer or film.

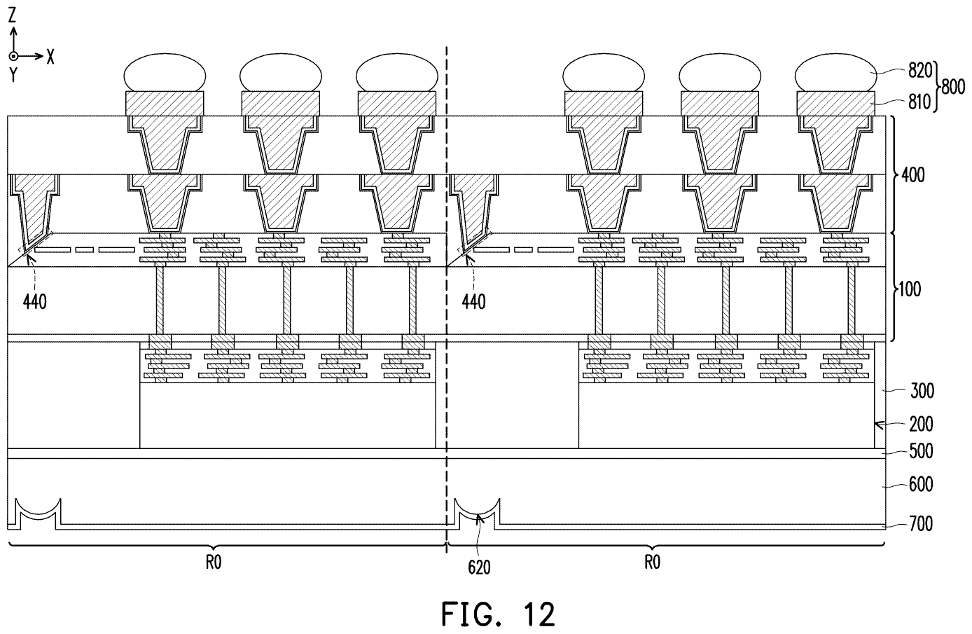

Referring to FIG. 12, in some embodiments, the whole structure depicted in FIG. 11 is flipped over (e.g., turned upside down), a plurality of conductive terminals 800 are formed over the redistribution circuit structure 400. The conductive terminals 800 each includes a conductive connector 810 and a solder region 820 disposed over the conductive connector 810, where the solder regions 820 are electrically coupled to the redistribution circuit structure 400 through the conductive connector 810, for example. However, the disclosure is not limited thereto; alternatively, the solder regions 820 may be omitted. In some embodiments, the conductive connector 810 may be micro bumps chip, connectors (e.g. controlled collapse chip connection (C4) bumps) or the like. When the solder regions 820 are used, the solder may include either eutectic solder or non-eutectic solder. The solder may include lead or be lead-free, and may include Sn—Ag, Sn—Cu, Sn—Ag—Cu, or the like.

Prior to forming the conductive terminals 800 and after flipping over the whole structure depicted in FIG. 11, the debonding process is performed on the another debond layer so to remove the another temporary carrier and the another debond layer, where the redistribution circuit structure 400 are accessibly revealed. In some embodiments, after flipping over the whole structure depicted in FIG. 11 and prior to debonding the another temporary carrier and the another debond layer, the whole structure depicted in FIG. 11 (e.g., the ARC layer 700) may be placed onto another temporary carrier (not shown) coated with another debond layer disposed thereon to securely hold the whole structure depicted in FIG. 11 during the sequent processes. The details of the another temporary carrier and the another debond layer may be similar to or substantially identical to the details of the temporary carrier and the debond layer previously described in FIG. 4, and thus are not repeated herein. In the embodiments of which the wafer-level carrier and the debond layer are presented, the debond layer is sandwiched between the whole structure depicted in FIG. 11 and the wafer-level carrier. Alternatively, the another temporary carrier may be a holding device. In the embodiments of which the holding device is employed, the whole structure depicted in FIG. 11 is disposed over and in physical contact with the holding device. For example, the holding device includes an adhesive tape, a carrier film or a suction pad.

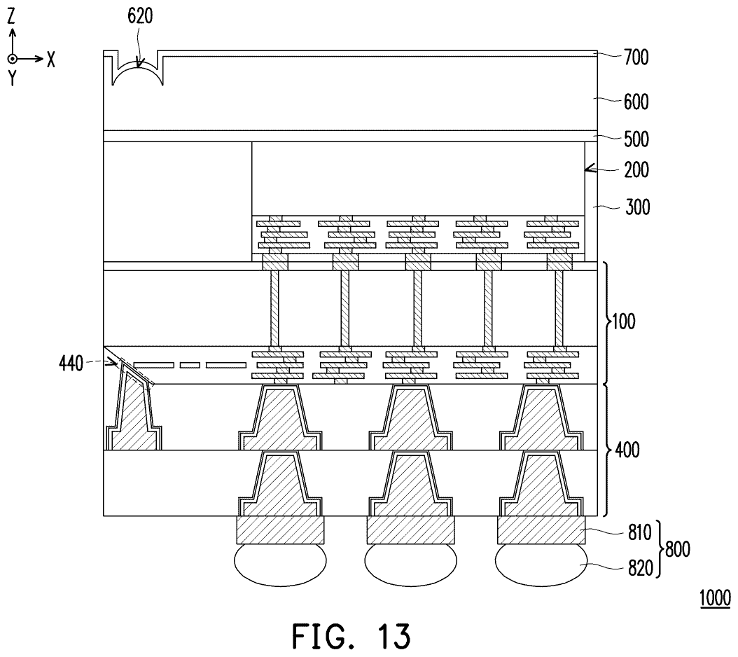

Referring to FIG. 13, in some embodiments, a dicing (or singulation) process is sequentially performed to cut through the whole structure depicted in FIG. 12 (including optical dies 1000 interconnected to each other) into individual and separated optical dies 1000. In one embodiment, the singulation process is a wafer dicing process including mechanical blade sawing or laser cutting. The disclosure is not limited thereto. Up to here, the optical dies 1000 are manufactured. Only one optical die 1000 is shown in FIG. 13 for illustrative purposes and simplicity.

Prior to performing the dicing (or singulation) process and after forming the conductive terminals 800, the debonding process is performed on the another debond layer so to remove the another temporary carrier and the another debond layer. Prior to performing the dicing (or singulation) process and after debonding the another temporary carrier and the another debond layer, the whole structure depicted in FIG. 12 is placed onto a dicing tape for performing the dicing (or singulation) process. In the embodiments of the dicing tape is used, the structure depicted in FIG. 12 is securely held by holding the conductive terminals 800.

Referring to FIG. 14 in conjunction with FIG. 21, in some embodiments, an interposer 5000A is provided, and one or more optical dies 1000, one or more semiconductor die 2000, one or more semiconductor dies 3000 and one or more semiconductor dies 4000 are then provided and disposed on the interposer 5000A. In some embodiments, in a vertical portion (e.g., the X-Y plane shown in FIG. 21) along the direction Z, the interposer 5000A has a region R1 for the placements of the semiconductor dies 2000 and 3000 and a region R2 for then placement of the optical dies 1000 and the placement of the semiconductor dies 4000, where the region R2 surrounds the region R1. In other words, the optical dies 1000 and the semiconductor dies 4000 are arranged along the edges of the interposer 5000A. For example, the semiconductor dies 3000 are arranged at two opposites sides of the semiconductor dies 2000 in the region R1, and the semiconductor dies 4000 and the optical dies 1000 are arranged along edges E1, E2, E3 and E4 of the region R1, see FIG. 14 in conjunction with FIG. 21.

The disclosure is not limited thereto; alternatively, the semiconductor dies 3000 may be arranged at two opposites sides of the semiconductor dies 2000, where the optical dies 1000 may be arranged along one edge of the edges E1, E2, E3 and E4 of the region R1, and the semiconductor dies 4000 may be arranged along the rest of the edges E1, E2, E3 and E4 of the region R1. Alternatively, the semiconductor dies 3000 may be arranged at two opposites sides of the semiconductor dies 2000, where the optical dies 1000 may be arranged along two edges (e.g., two opposites edges or two adjacent edges) of the edges E1, E2, E3 and E4 of the region R1, and the semiconductor dies 4000 may be arranged along the rest of the edges E1, E2, E3 and E4 of the region R1. Alternatively, the semiconductor dies 3000 may be arranged at two opposites sides of the semiconductor dies 2000, where the optical dies 1000 may be arranged along three edges of the edges E1, E2, E3 and E4 of the region R1, and the semiconductor dies 4000 may be arranged along the rest of the edges E1, E2, E3 and E4 of the region R1. Alternatively, the semiconductor dies 3000 may be arranged at two opposites sides of the semiconductor dies 2000, where the optical dies 1000 may be arranged along the edges E1, E2, E3 and E4 of the region R1, and the semiconductor dies 4000 are omitted. For illustrative purposes, only eight optical dies 1000, two semiconductor dies 2000, four semiconductor dies 3000, fourteen semiconductor dies 4000 are shown in FIG. 21, however the number of the optical dies 1000, the number of the semiconductor dies 2000, the number of the semiconductor dies 3000 and the number of the semiconductor dies 4000 can be selected and designated based on the demand and design requirements.

In some embodiments, the semiconductor dies 2000, 3000 and 4000 are bonded to and electrically coupled to the interposer 5000A through connectors 6000 by flip chip bonding, and the optical dies 1000 are bonded to and electrically coupled to the interposer 5000A by the conductive terminals 800. For example, the optical dies 1000 and the semiconductor dies 2000, 3000 are electrically coupled to and electrically communicated to each other through the interposer 5000A.

For example, as shown in FIG. 14, each of the semiconductor dies 2000 includes a semiconductor substrate 2100 having a surface S2100t (may referred to as an active or front surface) and a surface S2100b (may referred to as a non-active or rear surface) opposite to the surface S2100t, an interconnect structure 2200 disposed over the surface S2100t of the semiconductor substrate 2100, a plurality of conductive vias 2300 disposed over and electrically coupled to the interconnect structure 2200, where the interconnect structure 2200 is disposed between the semiconductor substrate 2100 and the conductive vias 2300. In some embodiments, the semiconductor substrate 2100 is a silicon substrate including active devices (e.g., transistors and/or memories such as N-type metal-oxide semiconductor (NMOS) and/or P-type metal-oxide semiconductor (PMOS) devices, or the like) and/or passive devices (e.g., resistors, capacitors, inductors or the like) formed therein. In some embodiments, such active devices and passive devices are formed in a front-end-of-line (FEOL) process. In an alternative embodiment, the semiconductor substrate 2100 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 2100 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the interconnect structure 2200 includes a dielectric structure 2220 (including one or more inter-dielectric layers) and one or more patterned conductive layers 2240 stacked alternately. For examples, the inter-dielectric layers of the dielectric structure 2220 are silicon oxide layers, silicon nitride layers, silicon oxy-nitride layers, or dielectric layers formed by other suitable dielectric materials, and are formed by deposition or the like. For examples, the patterned conductive layers 2240 are patterned copper layers or other suitable patterned metal layers, and are formed by electroplating or deposition. However, the disclosure is not limited thereto. Alternatively, the patterned conductive layers 2240 may be formed by a single or dual-damascene method. The number of the inter-dielectric layers of the dielectric structure 2220 and the number of the patterned conductive layers 2240 may be less than or more than what is depicted in FIG. 14, and may be selected and/or designated depending on the demand and/or design layout; the disclosure is not specifically limited thereto. In some embodiments, the interconnect structure 2200 is formed in a BEOL process. In certain embodiments, as shown in FIG. 14, the patterned conductive layers 2240 are sandwiched between the inter-dielectric layers of the dielectric structure 2220, where a surface of the outermost layer of the patterned conductive layers 2240 is exposed by an outermost layer of the inter-dielectric layers of the dielectric structure 2220 to connect to later formed component(s) for electrical connection (e.g. with the conductive vias 2300), and a surface of an innermost layer of the patterned conductive layers 2240 is exposed by an innermost layer of the inter-dielectric layers of the dielectric structure 2220 and electrically connected to the active devices and/or passive devices included in the semiconductor substrate 2100.

In some embodiments, the conductive vias 2300 are formed on the interconnect structure 2200 and over the semiconductor substrate 2100. In some embodiments, as shown in FIG. 14, the conductive vias 2300 each physically contact the surface of the outermost layer of the patterned conductive layers 2240 exposed by the outermost layer of the inter-dielectric layers of the dielectric structure 2220. Through the interconnect structure 2200, the conductive vias 2300 are electrically connected to the active devices and/or passive devices included in the semiconductor substrate 2100. In some embodiments, the conductive vias 2300 in physical contact with the interconnect structure 2200 are extended away from the outermost surface of the interconnect structure 2200. For simplification, only five conductive vias 2300 are presented in each semiconductor die 2000 of FIG. 14 for illustrative purposes, however it should be noted that more than five conductive vias 2300 may be formed; the disclosure is not limited thereto.

In some embodiments, the conductive vias 2300 are formed by photolithography, plating, photoresist stripping processes or any other suitable method. The plating process may include an electroplating plating, an electroless plating, or the like. For example, the conductive vias 2300 is formed by, but not limited to, forming a mask pattern (not shown) covering the interconnect structure 2200 with opening holes (not shown) corresponding to the surface of the outermost layer of the patterned conductive layers 2240 exposed by the outermost layer of the inter-dielectric layers of the dielectric structure 2220, forming a metallic material to fill the opening holes formed in the mask pattern to form the conductive vias 2300 by electroplating or deposition, and then removing the mask pattern. The mask pattern may be removed by acceptable ashing process and/or photoresist stripping process, such as using an oxygen plasma or the like. In one embodiment, the material of the conductive vias 2300 includes a metal material such as copper or copper alloys, or the like.

In some embodiments, in a vertical projection on the surface S2100t of the semiconductor substrate 2100 along the (stacking) direction Z of the semiconductor substrate 2100, the interconnect structure 2200 and the conductive vias 2300, the conductive vias 2300 may independently be in a circle-shape, an ellipse-shape, a triangle-shape, a rectangle-shape, or the like. The shape of the conductive vias 2300 is not limited in the disclosure. The shape and number of the conductive vias 2300 may be selected and/or designated depending on the demand and/or design layout.

Alternatively, the conductive vias 2300 may be formed by, but not limited to, conformally forming a metallic seed layer over the interconnect structure 2200, forming a mask pattern (not shown) covering the metallic seed layer with opening holes (not shown) corresponding to the surface of the outermost layer of the patterned conductive layers 2240 exposed by the outermost layer of the inter-dielectric layers of the dielectric structure 2220, forming a metallic material to fill the opening holes formed in the mask pattern by electroplating or deposition, removing the mask pattern, and then removing the metallic seed layer not covered by the metallic material to form the conductive vias 2300. In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, the semiconductor dies 2000 each further includes a seal ring (not shown) embedded in the interconnect structure 2200 to surround the patterned conductive layers 2240 inside the dielectric structure 2220. Owing to the seal ring, the interconnect structure 2200 (e.g., of the dielectric structure 2220 and the patterned conductive layers 2240) is protected from the physical damages and/or the moistures or hydrogen attacks for the environment. In some embodiments, for each semiconductor die 2000, a sidewall of the semiconductor substrate 2100 and a sidewall of the interconnect structure 2200 are substantially aligned with each other in the direction Z and together constitute a sidewall of the semiconductor die 2000.

It is appreciated that, in some embodiments, the semiconductor dies 2000 independently described herein may be referred to as a semiconductor chip or an integrated circuit (IC). In some embodiments, the semiconductor dies 2000 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 2000 independently may be or include a digital chip, an analog chip or a mixed signal chip. The semiconductor dies 2000 independently may be a chip or an IC of combination-type, such as a WiFi chip simultaneously including both of a RF chip and a digital chip.

In alternative embodiments, the semiconductor dies 2000 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc.; a combination thereof; or the like.

In some embodiments, the types of all of the semiconductor dies 2000 are identical. In alternative embodiments, the types of some of the semiconductor dies 2000 are different from each other, while the types of some of the semiconductor dies 2000 are identical types. In further alternative embodiments, the types of all of the semiconductor dies 2000 are different. In some embodiments, the sizes of all of the semiconductor dies 2000 are the same. In alterative embodiments, the sizes of some of the semiconductor dies 2000 are different from each other, while the sizes of some of the semiconductor dies 2000 are the same sizes. In further alternative embodiments, the sizes of all of the semiconductor dies 2000 are different. In some embodiments, the shapes of all of the semiconductor dies 2000 are identical. In alternative embodiments, the shapes of some of the semiconductor dies 2000 are different from each other, while the shapes of some of the semiconductor dies 2000 are identical. In further alternative embodiments, the shapes of all of the semiconductor dies 2000 are different. The types, sizes and shapes of each of the semiconductor dies 2000 are independent from each other, and may be selected and designed based on the demand and design layout, the disclosure is not limited thereto.

For example, as shown in FIG. 14, each of the semiconductor dies 3000 includes a carrier die 3100 having a surface S3100t and a surface S3100b opposing to the surface S3100t, an interconnect structure 3200 (including a dielectric structure 3220 and patterned conductive layers 3240) disposed over the surface S3100t of the carrier die 3100 and electrically coupled to the carrier die 3100, a plurality of conductive vias 3300 disposed over and electrically coupled to the interconnect structure 3200, a plurality of stacking dies 3400 disposed over the surface S3100b of the carrier die 3100 and electrically coupled to the carrier die 3100, and an encapsulant 3500, where the stacking dies 3400 are sequentially stacked on (along the direction Z) and electrically coupled to the carrier die 3100, the interconnect structure 3200 is disposed between and electrically coupled to the conductive vias 3300 and the carrier die 3100, and the encapsulant 3500 encapsulates the stacking dies 3400 and covers the carrier die 3100 exposed by the stacking dies 3400. In some embodiments, the carrier die 3100 is disposed between the encapsulant 3500 and the interconnect structure 3200 and between the stacking dies 3400 and the interconnect structure 3200, and the conductive vias 3300 is protruded away from a surface of the interconnect structure 3200.

It is noted that, each of the carrier die 3100 and the stacking dies 3400 may further include an interconnect structure (not shown). The carrier die 3100 described herein may be referred as a semiconductor chip or an IC. In some embodiments, the carrier die 3100 includes one or more digital chips, analog chips or mixed signal chips, such as an ASIC chip, a sensor chip, a wireless and RF chip, a logic chip or a voltage regulator chip. The logic chip may be a CPU, a GPU, a SoC, a microcontroller, or the like. In some embodiments, each of the stacking dies 3400 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash a wide I/O memory (WIO) die, a high bandwidth memory (HBM) die, the like, etc.). That is to say, the semiconductor dies 3000 each includes a hybrid memory cube (HMC) module, a HBM module, or the like; in some embodiments. For example, the stacking dies 3400 of each semiconductor die 3000 may be HBM dies, and the carrier die 3100 may be a logic die providing control functionality for these memory dies. The details, formation and material of the interconnect structure 3200 (including the dielectric structure 3220 and the patterned conductive layers 3240) and the conductive vias 3300 is similar to or substantially identical to the details, formation and material of the interconnection structure 2200 (including the dielectric structure 2220 and the patterned conductive layers 2240) and the conductive vias 2300, and thus are not repeated herein for brevity.

In some embodiments, the material of the encapsulant 3500 includes a molding compound, a molding underfill, a resin (such as epoxy), or the like. In some alternative embodiments, the material of the encapsulant 3500 includes nitride such as silicon nitride, oxide such as silicon oxide, phosphosilicate glass (PSG), borosilicate glass (BSG), boron-doped phosphosilicate glass (BPSG), a combination thereof, or the like. In yet alternative embodiments, the material of each of the encapsulant 3500 includes an organic material (e.g., epoxy, polyimide (PI), PBO, or the like), or the mixture of inorganic and organic materials (e.g., the mixture of silicon oxide and epoxy, or the like). In some embodiments, the encapsulant 3500 may be formed by a molding process, such as a compression molding process. In some alternative embodiments, the encapsulant 3500 may be formed through suitable fabrication techniques such as CVD (e.g., high-density plasma chemical vapor deposition (HDPCVD) or plasma-enhanced chemical vapor deposition (PECVD)). As illustrated in FIG. 14, for example, a back (or non-active) surface (not labeled) of the semiconductor die 3000 includes a surface of the encapsulant 3500 and a surface of outermost stacking die 3400, where the surface of the encapsulant 3500 and the surface of outermost stacking die 3400 are substantially leveled with and substantially coplanar to each other. Alternatively or in addition to, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like may be included to substitute one or some of the semiconductor dies 3000 or be further adopted. The type of the semiconductor dies 3000 independently may be selected and/or designated depending on the demand and/or design layout, and thus is not specifically limited in the disclosure.

In some embodiments, the types of all of the semiconductor dies 3000 are identical. In alternative embodiments, the types of some of the semiconductor dies 3000 are different from each other, while the types of some of the semiconductor dies 3000 are identical types. In further alternative embodiments, the types of all of the semiconductor dies 3000 are different. In some embodiments, the sizes of some of the semiconductor dies 3000 are different from each other, while the sizes of some of the semiconductor dies 3000 are the same sizes. In alternative embodiments, the sizes of all of the semiconductor dies 3000 are the same. In further alternative embodiments, the sizes of all of the semiconductor dies 3000 are different. In some embodiments, the shapes of some of the semiconductor dies 3000 are different from each other, while the shapes of some of the semiconductor dies 3000 are identical. In alternative embodiments, the shapes of all of the semiconductor dies 3000 are identical. In further alternative embodiments, the shapes of all of the semiconductor dies 3000 are different. The types, sizes and shapes of each of the semiconductor dies 3000 are independent from each other, and may be selected and designed based on the demand and design layout, the disclosure is not limited thereto.

For example, the semiconductor dies 4000 may be input/output (I/O) interface dies. As shown in FIG. 21, the semiconductor dies 2000 may be SoCs, the semiconductor dies 3000 may be HBM modules, and the semiconductor dies 4000 may be I/O interface dies. The structure, formation and material of the semiconductor die 4000 may be similar to or substantially identical to the structure, formation and material of the semiconductor dies 2000, and thus are not repeated herein. For example, the connectors 6000 includes solder regions. The connectors 6000 independently may include lead or be lead-free, and may include Sn—Ag, Sn—Cu, Sn—Ag—Cu, or the like. The connectors 6000 independently may be referred to as solder regions, solder elements, conductive connectors, or conductive elements. For example, the connectors 6000 include solder balls, solder paste, or the like.

For example, as shown in FIG. 14, the interposer 5000A includes a plurality of bridge dies 5100 (e.g., including bridge dies 5100A, 5100B, and/or 5100C), a plurality of conductive pillars 5200, a redistribution circuit structure 5300 (e.g., including a dielectric structure 5320 and one or more metallization layers 5340), a redistribution circuit structure 5400 (e.g., including a dielectric structure 5420 and one or more metallization layers 5440), a plurality of conductive vias 5500, an encapsulant 5600, and a plurality of conductive terminals 5700 (e.g., including conductive connector 5720 and solder regions 5740 disposed thereon). In addition to or alternatively, the redistribution circuit structure 5300 and/or the redistribution circuit structure 5400 may be omitted. The interposer 5000A may include a plurality of bridge dies 5100 (e.g., including bridge dies 5100A, 5100B, and/or 5100C), a plurality of conductive pillars 5200, a redistribution circuit structure 5300 (e.g., including a dielectric structure 5320 and one or more metallization layers 5340), a plurality of conductive vias 5500, an encapsulant 5600, and a plurality of conductive terminals 5700 (e.g., including conductive connector 5720 and solder regions 5740 disposed thereon). Alternatively, the interposer 5000A may include a plurality of bridge dies 5100 (e.g., including bridge dies 5100A, 5100B, and/or 5100C), a plurality of conductive pillars 5200, a redistribution circuit structure 5400 (e.g., including a dielectric structure 5420 and one or more metallization layers 5440), a plurality of conductive vias 5500, an encapsulant 5600, and a plurality of conductive terminals 5700 (e.g., including conductive connector 5720 and solder regions 5740 disposed thereon). Or, the interposer 5000A may include a plurality of bridge dies 5100 (e.g., including bridge dies 5100A, 5100B, and/or 5100C), a plurality of conductive pillars 5200, a plurality of conductive vias 5500, an encapsulant 5600, and a plurality of conductive terminals 5700 (e.g., including conductive connector 5720 and solder regions 5740 disposed thereon). In addition to or alternatively, the conductive vias 5500 may be omitted. The interposer 5000A may be referred to as an interconnect substrate, an interconnect structure, an interconnection substrate or an interconnection structure.

As shown in FIG. 14, the bridge dies 5100A, 5100B, 5100C of the bridge dies 5100 and the conductive pillars 5200 are encapsulated in the encapsulant 5600, where the redistribution circuit structure 5300 and the redistribution circuit structure 5400 are disposed at two opposite sides of the encapsulant 5600 and electrically coupled to the bridge dies 5100A, 5100B, 5100C of the bridge dies 5100 and the conductive pillars 5200, for example. In some embodiments, the conductive vias 5500 are disposed over and electrically coupled to the redistribution circuit structure 5300, where the redistribution circuit structure 5300 is disposed between the conductive vias 5500 and the encapsulant 5600. In some embodiments, the conductive terminals 5700 are disposed over and electrically coupled to the redistribution circuit structure 5400, where the redistribution circuit structure 5400 is disposed between the conductive terminals 5700 and the encapsulant 5600. As shown in FIG. 14, some of the conductive vias 5500 may be electrically coupled to the conductive terminals 5700 through the redistribution circuit structure 5300, the conductive pillars 5200, and the redistribution circuit structure 5400, and some of the conductive vias 5500 may be electrically coupled to the conductive terminals 5700 through the redistribution circuit structure 5300, the bridge dies 5100, and the redistribution circuit structure 5400. The details, formation and material of the conductive pillars 5200 may be similar to or substantially identical to the details, formation and material of the through vias 120 (previously described in FIG. 1), the details, formation and material of the redistribution circuit structures 5300 and 5400 may be similar to or substantially identical to the details, formation and material of the interconnection structure 130 or the redistribution circuit structure 400 (previously described in FIG. 1), the details, formation and material of the conductive vias 5500 may be similar to or substantially identical to the details, formation and material of the conductive vias 2300 previously discussed, the details, formation and material of the encapsulant 5600 may be similar to or substantially identical to the details, formation and material of the encapsulant 3500 previously discussed, and the details, formation and material of the conductive terminals 5700 may be similar to or substantially identical to the details, formation and material of the conductive terminals 800 (previously described in FIG. 1), and thus are not repeated herein for brevity.

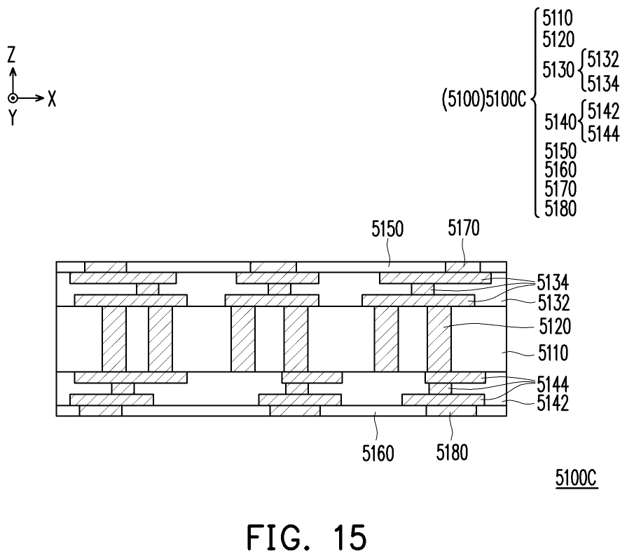

In some embodiments, as shown in FIG. 14 and FIG. 15, the bridge dies 5100A, 5100B and 5100C are substantially identical in the structure and functionality, except their lateral sizes (e.g., the dimensions in the X-Y plane). For example, in the plane view (e.g., the X-Y plane) or in the cross-sectional view of FIG. 14, a size of the bridge dies 5100A is less than a size of the bridge dies 5100B and a size of the bridge die(s) 5100C, and the size of the bridge dies 5100B is less than the size of the bridge die(s) 5100C.

In a non-limiting embodiment of the bridge dies 5100 as shown in FIG. 15, where one bridge die 5100C is emphasized as exemplary example of a general structure of the bridge dies 5100 (such as 5100A, 5100B and 5100C), but the disclosure is not limited thereto. As shown in FIG. 15, the bridge die 5100C may include a substrate 5110, a plurality of conductive pillars 5120 penetrating through the substrate 5110, an interconnect structure 5130 (including a dielectric structure 5132 and one or more metallization layers 5134) disposed over the substrate 5110 and electrically coupled to the conductive pillars 5120, an interconnect structure 5140 (including a dielectric structure 5142 and one or more metallization layers 5144) disposed over the substrate 5110 and electrically coupled to the conductive pillars 5120, a dielectric layer 5150 disposed over the interconnect structure 5130, a dielectric layer 5160 disposed over the interconnect structure 5140, a plurality of conductive vias 5170 disposed over and electrically coupled to the interconnect structure 5130 and laterally covered by the dielectric layer 5150, and a plurality of conductive vias 5180 disposed over and electrically coupled to the interconnect structure 5140 and laterally covered by the dielectric layer 4170, where the conductive vias 5170 penetrate through the dielectric layer 5150, and the conductive vias 5180 penetrate through the dielectric layer 5160. For example, an illustrated top surface of the dielectric layer 5150 is substantially level with illustrated top surfaces of the conductive vias 5170, and an illustrated bottom surface of the dielectric layer 5160 is substantially level with illustrated bottom surfaces of the conductive vias 5180. In other words, the illustrated top surface of the dielectric layer 5150 may be substantially coplanar to the illustrated top surfaces of the conductive vias 5170, and the illustrated bottom surface of the dielectric layer 5160 is substantially coplanar to the illustrated bottom surfaces of the conductive vias 5180. In alternative embodiments, the interconnect structure 5130 and/or the interconnect structure 5140 may be omitted. In addition to or alternative embodiments, the dielectric layer 5150 and/or the dielectric layer 5160 may be omitted. In addition to or alternative embodiments, the conductive vias 5170 and/or the conductive vias 5180 may be omitted.

In some embodiments, the substrate 5110 is a bulk semiconductor substrate, a silicon-on-insulator (SOI) substrate, a multi-layered semiconductor substrate, or the like. The semiconductor material of the substrate 5110 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 5110 may be doped or undoped. The substrate 5110 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. Alternatively, the substrate 5110 may be substantially free of active devices and passive devices, and merely provide routing functions. The formations and materials of the conductive pillars 5120, the interconnect structures 5130, 5140, the dielectric layers 5150, 5160 and the conductive vias 5170, 5180 may be similar to or be substantially identical to the through vias 120, the interconnection structure 130, the dielectric layer 140 and the conductive vias 150 previously described in FIG. 1, and thus are not repeated herein for brevity. The conductive pillars 5120 may be sometimes referred to as through-substrate-vias or through-silicon-vias as the substrate 5110 is a silicon substrate. The interconnect structures 5130 and/or 5140 may be sometimes referred to as an interconnection, an interconnect structure, an interconnect, or a routing structure.

Continued on FIG. 14, after bonding the optical dies 1000 and the semiconductor dies 2000, 3000, 4000 to the interposer 5000A, a plurality of protective structures 50 are disposed on the optical dies 1000, respectively. For example, each of the protective structures 500 may include a supporting plug 51 and a dielectric layer 52 lining a sidewall and bottom of the supporting plug 51. The supporting plugs 51 may be made of silicon, which may be referred to as silicon plugs. The dielectric layer 52 may be made of polymer or the like. The protective structures 50 are mounted onto the optical dies 1000 by respectively engaging the dielectric layers 52 of the protective structures 50 with the lens structures 620 of the optical dies 1000 (coated with the ARC layer 700 thereon), where the dielectric layers 52 of the protective structures 50 fill up the recesses R formed in the supporting structure 600 for securely fastening the protective structures 50 onto the optical dies 1000, thereby protecting the lens structures 620 of the optical dies 1000 from the sequent processes.

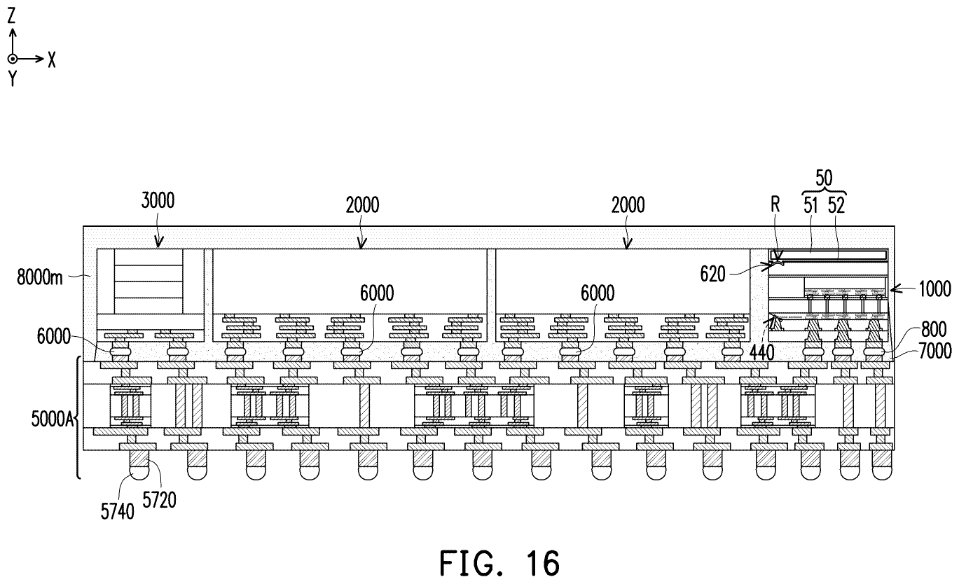

Referring to FIG. 16, in some embodiments, an underfill 7000 fills gaps between the semiconductor dies 2000, 3000, 4000 and the interposer 5000A (e.g., the redistribution circuit structure 5300) and between the optical dies 1000 and the interposer 5000A (e.g., the redistribution circuit structure 5300). The sidewalls of the conductive vias 2200, 3200, 5500, the solder regions 6000 and the conductive terminals 800 are wrapped by the underfill 7000. The underfill 7000 may be any acceptable material, such as a polymer, epoxy resin, molding underfill, or the like, for example. The underfill 7000 may be formed by underfill dispensing, a capillary flow process, or any other suitable method. In some embodiments, the underfill 7000 further extends onto sidewalls of the optical dies 1000, the protective structures 50 and the semiconductor dies 2000, 3000, 4000 and fills gaps between the optical dies 1000, the protective structures 50 and the semiconductor dies 2000, 3000, 4000. Owing to the underfill 7000, bonding strengths between the optical dies 1000 and the redistribution circuit structure 5300, between the semiconductor dies 2000 and the redistribution circuit structure 5300, between the semiconductor dies 3000 and the redistribution circuit structure 5300 and between the semiconductor dies 4000 and the redistribution circuit structure 5300 are enhanced. The underfill 7000 may be referred to as a dielectric material.

Continued on FIG. 16, in some embodiments, the optical dies 1000, the protective structures 50, the semiconductor dies 2000, 3000, 4000 and the underfill 7000 are encapsulated in an insulating encapsulant material 8000m, where the optical dies 1000, the protective structures 50, the semiconductor dies 2000, 3000, 4000 and the underfill 7000 are not accessibly revealed by the insulating encapsulant material 8000m. In some embodiments, the insulating encapsulant material 8000m include polymers (such as epoxy resins, phenolic resins, silicon-containing resins, or other suitable resins), dielectric materials, or other suitable materials. In an alternative embodiment, the insulating encapsulant material 8000m may include an acceptable insulating encapsulation material. The insulating encapsulant 8000 may further include inorganic filler or inorganic compound (e.g., silica, clay, and so on) which can be added therein to optimize CTE thereof, the disclosure is not limited thereto. For example, the insulating encapsulant material 8000m is formed over the optical dies 1000, the protective structures 50, the semiconductor dies 2000, 3000, 4000 and the underfill 7000 by over-molding.

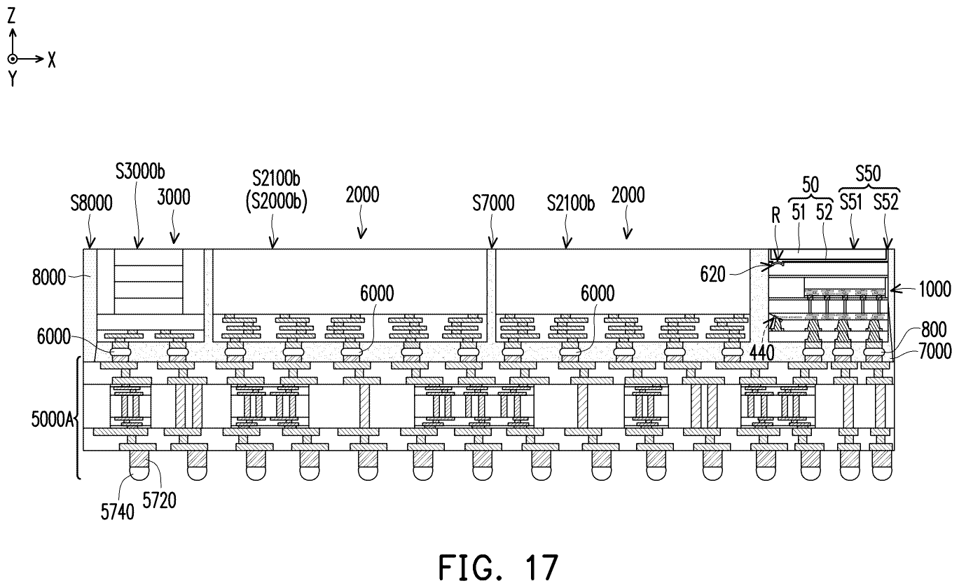

Referring to FIG. 17, in some embodiments, a planarizing process is performed on the insulating encapsulant material 8000m to form an insulating encapsulant 8000 accessibly revealing the protective structures 50 disposed over the optical dies 1000. For example, the insulating encapsulant 8000 laterally encapsulates the protective structures 50 and the semiconductor dies 2000, 3000, 4000. As shown in FIG. 17, a surface S8000 of the insulating encapsulant 8000 may be substantially level with surfaces S2000 (e.g., S2100b) of the semiconductor dies 2000, surfaces S3000 of the semiconductor dies 3000 and surfaces S50 of the protective structures 50, where the surfaces S50 of the protective structures 50 each includes a surface S51 of the supporting plug 51 and a surface S52 of the dielectric layer 52. In other words, the surface S8000 of the insulating encapsulant 8000 may be substantially coplanar to the surfaces S2000 (e.g., S2100b) of the semiconductor dies 2000, the surfaces S3000 of the semiconductor dies 3000, and the surfaces S50 of the protective structures 50. That is, the semiconductor dies 2000, 3000 and the protective structures 50 disposed over the optical dices 1000 are accessibly revealed by the insulating encapsulant 8000. As shown in FIG. 17 the insulating encapsulant 8000 may further accessibly reveal the underfill 700. As shown in FIG. 17, the surface S8000 of the insulating encapsulant 8000 may be substantially level with a surface S7000 of the underfill 7000. In other words, the surface S8000 of the insulating encapsulant 8000 may be substantially coplanar to the surface S7000 of the underfill 7000. In addition to or alternatively, the insulating encapsulant 8000 may further accessibly reveal the semiconductor dies 4000. In such case the surface S8000 of the insulating encapsulant 8000 may be substantially level with a surfaces S4000 of the semiconductor dies 4000. In other words, the surface S8000 of the insulating encapsulant 8000 may be substantially coplanar to the surfaces S4000 of the semiconductor dies 4000. The insulating encapsulant 8000 may be referred to as an insulating encapsulation, an encapsulation, an encapsulant, a dielectric encapsulation, a dielectric encapsulant, or a dielectric material. Owing to the insulating encapsulant 8000, the optical dies 1000 and the semiconductor dies 2000, 3000, 4000 are protected from the damages caused by the external contacts. The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method.

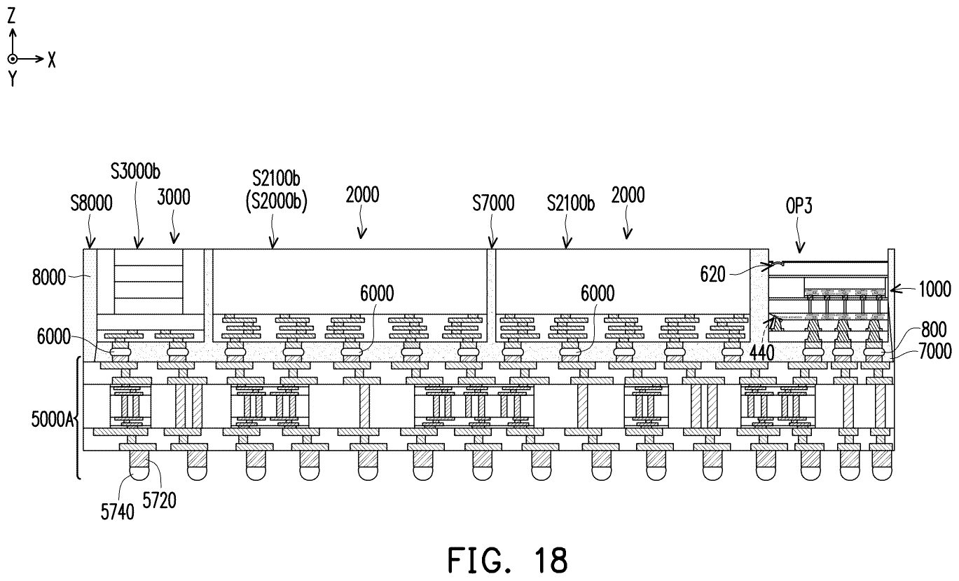

Referring to FIG. 18, in some embodiments, the protective structures 50 are removed from the optical dies 1000. The removing process may be performed by etching. After the removal of the supporting structures 50, the optical dies 1000 are accessibly revealed by the insulating encapsulant 8000. In other words, the optical dies 1000 are exposed by a plurality of openings OP3 disposed overlying thereto which are formed due to the removal of the protective structures 50 from the structure depicted in FIG. 17.

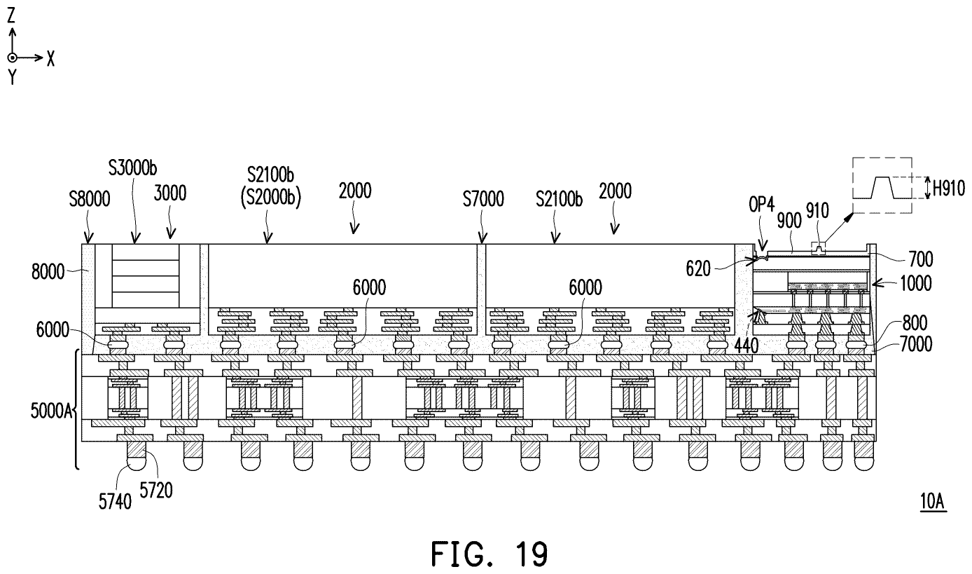

Referring to FIG. 18 and FIG. 19, in some embodiments, a plurality of sockets 900 are provided and attached to the optical dies 1000, where the sockets 900 are disposed on the ARC layer 700 over the supporting substrate 600. In some embodiments, the sockets 900 each has at least one opening OP4 exposing a portion of the ARC layer 700 disposed directly on the lens structure 620 of the respective optical die 1000. The sockets 900 may be attached to the optical dies 1000 by an adhesive, such as a liquid adhesive, an adhesive film, or the like; the disclosure is not limited thereto, as long as the sockets 900 can be securely fixed onto the optical dies 1000. In some embodiments, in the cross-section view along the direction Z, a shape of each of sockets 900 has a cup-shape, where a sidewall of the cup shape is connected to the sidewall of the openings OP3, and a bottom of the cup shape is connected to the ARC layer 700 and includes at least one protrusion 910 disposed on the bottom and protruding away from the ARC layer 700. As shown in FIG. 19, the bottom of the cup-shape of each socket 900 may have at least one opening OP4 exposing the portion of the ARC layer 700 disposed directly on the lens structure 620 of the respective optical die 1000. Owing to the protrusions 910 of the sockets 900, an optical fiber (e.g., 9000) can be securely assembled onto a respective one of the optical dies 1000. Due to the sockets 900, the accuracy and precision of placements of the optical fibers (e.g., 9000) and the alignments between the optical fibers (e.g., 9000) and the optical dies 1000 are greatly enhanced and improved. In some embodiments, a thickness H910 of the protrusions 910 approximately ranges from 300 μm to 500 μm, with a deviation of ±15 μm. The sockets 900 may be referred to as optical sockets. As shown in FIG. 19, the sockets 900 may be vertically installed on the optical dies 1000. For example, an outermost surface (not labeled) of the sockets 900 are below or at the same level of the surface S8000 of the insulating encapsulant 8000. In some embodiments, the structure depicted in FIG. 19 can be considered as a structure of chip-on-wafer (CoW). In other words, the structure depicted in FIG. 19 is a CoW structure 10A, for example.

Referring to FIG. 20, in some embodiments, after installing the sockets 900 vertically onto the optical dies 1000, a plurality of photonic components 9000 are removably installed onto the sockets 900, where the protrusions 910 of the sockets 900 are partially inserted into the photonic components 9000 for ensuring the placements of the photonic components 9000 and the alignments between the photonic components 9000 and the optical dies 1000. Up to here, the semiconductor package SP1 is manufactured. The photonic components 9000 may be referred to as optical fibers. For example, the photonic components 9000 are or include fiber array units. In some embodiments, each of the optical components 9000 includes a lens structure 9100 and a reflector 9200 therein, where the lens structure 9100 and the reflector 9200 are located at the optical path of the optical signal (e.g., L in FIG. 20 through FIG. 21) between the edge coupler 160 and the photonic component (e.g., an optical fiber, see 9000 in FIG. 20 through FIG. 21), where the lens structure 9100 and the reflector 9200 are optically coupled to each other. For example, the lens structures 9100 of the photonic components 9000 are optically coupled to the lens structures 620 of the optical dies 1000, where the lens structure 9100 of one photonic component 9000 and the lens structure 620 of a respective one optical die 1000 are paired to be cooperated with each other for achieving focus during the optical signal transmission of the optical signal (e.g., L in FIG. 20 through FIG. 21). In some embodiments, the reflectors 9200 are capable of reflecting a horizontal light into a vertical light, where an angle between the plane where the reflectors 9200 located at and the direction of the optical signal (e.g., L in FIG. 20 through FIG. 21) travels is about 45 degrees. The reflectors 9200 may be referred to as reflecting structures, mirrors, or mirror structures, where the reflectors 9200 is embedded inside the photonic components 9000 and posited at the optical path of an optical signal (e.g., L in FIG. 20 through FIG. 21) between the edge coupler 160 and the photonic component (e.g., an optical fiber, see 9000 in FIG. 20 through FIG. 21). As shown in FIG. 20 and FIG. 21, the photonic components 9000 extend beyond the footprint area of the optical dies 1000, for example.

As shown in FIG. 20, the optical light L is transmitted from an external device coupled to the photonic component 9000 to the optical die 100, where the optical light L is initially transmitted in the horizontal direction (e.g., the direction X and the direction Y) inside the photonic component 9000, then the optical light L is reflected by the reflector 9200 to transmit in the vertical direction (e.g., the direction Z) towards to the optical die 1000 by leaving the photonic component 9000 through the lens structure 9100. In such case, since the lens structure 9100 of one photonic component 9000 and the lens structure 620 of a respective one optical die 1000 are paired to be cooperated with each other for achieving focus during the optical signal transmission of the optical signal (e.g., the optical light L in FIG. 20 through FIG. 21), the optical light L is securely transmitted into the optical die 1000, then the optical light L is re-directed to the horizontal direction (e.g., the direction X and the direction Y) by being reflected by the reflector 440 laterally adjacent to the edge coupler 160 of the optical die 1000 so to optically couple to the edge coupler 160 of the optical die 1000. On the other hand, the optical light L can be transmitted from the optical die 1000 to the external device coupled to the photonic component 9000 by the by way of the above components in the reversed order. Due to the edge couplers 160 of the optical dies 1000, the bandwidth enlargement and lower polarization sensitivity of optical signals for the semiconductor package SP1 are ensured. As shown in FIG. 20, owing to the configuration of the sockets 900 and the optical dies 1000, not only the overall footprint of the semiconductor package SP1 (e.g., in the X-Y plane) can be decreased, a height difference H between surfaces S9000 of the photonic components 9000 and the surfaces S2000b of the semiconductors 2000 (or saying the surfaces S3000b of the semiconductors 3000 and/or the surface S8000 of the insulating encapsulant 800) is also greatly reduced to obtain a better flatness at the a backside of the semiconductor package SP1, which benefits the installation of heat dissipating elements (not shown). As shown in FIG. 20, the semiconductor package SP1 may include a structure of CoW.

However, the disclosure is not limited thereto; the CoW structure 10A may be further mounted to a circuit structure to form a semiconductor package SP2 equipped with photonic components 9000, see FIG. 22 and FIG. 23. Referring to FIG. 22 and FIG. 23, in some embodiments, the CoW structure 10A is placed over and mounted to a circuit substrate 60, then the photonic components 9000 are removably installed onto the sockets 900 of the CoW structure 10A, where the protrusions 910 of the sockets 900 are partially inserted into the photonic components 9000 for ensuring the placements of the photonic components 9000 and the alignments between the photonic components 9000 and the optical dies 1000. The details of the CoW structure 10A have been previously described in FIG. 1 through FIG. 19, the details of the photonic components 9000 have been previously described in FIG. 20, and thus are not repeated herein for brevity.

In some embodiments, the circuit substrate 60 includes a body 61, metallization layers 62 and vias (not shown) interconnected therebetween and disposed inside the body 61, and a plurality of bonding pads 63, 64 vertically distributed at two opposite sides of the body 61 and connected to the metallization layers 62 and vias. As shown in FIG. 22, the body 61 has a surface S61t and a surface S61b opposing to the surface S61t, where the bonding pads 63 are accessibly revealed by the surface S61t of the body 61, and the bonding pads 64 are accessibly revealed by the surface S61b of the body 61. The body 61 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some alternative embodiments, the body 61 is a SOI substrate, where the SOI substrate may include a layer of a semiconductor material such as epitaxial silicon, germanium, silicon germanium, SOI, silicon germanium on insulator (SGOI), or combinations thereof. In further alternative embodiments, the body 61 is based on an insulating core, such as a fiberglass reinforced resin core. One example core material is fiberglass resin such as flame-retardant class 4 (FR4). Alternatives for the core material may include bismaleimide triazine (BT) resin, or alternatively, other printed circuit board (PCB) materials or films. In yet further alternative embodiments, the body 61 is a build-up film such as Ajinomoto build-up film (ABF) or other suitable laminates. In one embodiment, the body 61 may include active and/or passive devices (not shown), such as transistors, capacitors, resistors, combinations thereof, or the like which may be used to generate the structural and functional requirements of the design for the semiconductor package. The active and/or passive devices may be formed using any suitable methods. However, the disclosure is not limited thereto; in an alternative embodiment, the body 61 may be substantially free of active and/or passive devices.

The metallization layers 62 and vias together form a functional circuitry providing routing functionality for the circuit substrate 60. The metallization layers 62 and vias embedded in the body 61 may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). The bonding pads 63, 64 are used to provide electrical connection with external component(s) for the circuit substrate 60. In some embodiments, the bonding pads 63, 64 are located at two opposite sides of the body 61 along the direction Z and electrically connected to each other through the metallization layers 62 and vias. The formation and material of the bonding pads 63, 64 along with the metallization layers 62 and vias may be similar to or substantially identical to the formation and material of the redistribution circuit structure 5400 previously described in FIG. 14, and thus are not repeated herein for brevity. As shown in FIG. 22, for example, the CoW structure 10A is connected to the bonding pads 63 of the circuit substrate 60 through the conductive terminals 5700.

In some embodiments, one or more surface devices (not shown) may be optionally connected to the circuit substrate 60. The surface devices may be, for example, used to provide additional functionality or programming to the CoW structure 10A. The surface devices may include surface mount devices (SMDs) or an integrated passive devices (IPDs) that include passive devices such as resistors, inductors, capacitors, jumpers, combinations of these, or the like that are desired to be connected to and utilized in conjunction with the CoW structure 10A. The surface devices may be disposed at one side or two opposite sides of the substrate in the direction Z. The number of the surface devices are not limited, and may be selected based on the demand and design requirement. The disclosure is not limited thereto. For example, the surface devices are electrically connected to the CoW structure 10A through the circuit substrate 60. In some embodiments, the circuit substrate 60 may be referred to as a redistribution substrate.

In some embodiments, an underfill 20 is formed on the circuit substrate 60. As shown in FIG. 22, for example, the underfill 20 fills the gap between the CoW structure 10A and the circuit substrate 60, and wraps sidewalls of the conductive terminals 5700. Owing to the underfill 20, the bonding strength between the CoW structure 10A and the circuit substrate 60 is enhanced. The material and formation of the underfill 20 may be the same or similar to the material and formation of underfill 7000 previously described in FIG. 16, and thus are not repeated herein for simplicity. However, the disclosure is not limited thereto; alternatively, the underfill 20 may be optionally omitted.

In some embodiments, after mounting the CoW structure 10A to the circuit substrate 60, a supporting structure 30 is provided and mounted to the circuit substrate 60 through a bonding element 40. In some embodiments, the supporting structure 30 is attached to the circuit substrate 60 using the bonding element 40. For example, a bottom surface (not labeled) of the supporting structure 30 is adhered to an illustrated top surface (e.g., S61t) of the circuit substrate 60 through the bonding element 40, where the supporting structure 30 surrounds the CoW structure 10A. In some embodiments, in the plane view (e.g., the X-Y plane) as shown in FIG. 23, the supporting structure 30 is in a form of a full (continuous) frame annulus having an inner sidewall (not labeled) facing the sidewall of the CoW structure 10A and an outer sidewall (not labeled) opposite to the inner sidewall. For example, the supporting structure 30 is next to and separated from the CoW structure 10A by a gap, in the plane view. Owing to the supporting structure 30, the loading effect (e.g., between a central region (disposed with the CoW structure 10A) and a peripherical region surrounding the central region) of the circuit substrate 60 is suppressed, the warpage control is achieved.

The supporting structure 30 may be referred to as a ring structure. The supporting structure 30 has a closed, full frame shape of rectangular annulus in the plane view of FIG. 23 for illustrative purposes, however the disclosure is not limited thereto. Alternatively, the supporting structure 30 may have a closed, continuous frame shape of circular annulus, elliptical annulus, other suitable polygonal annulus in the plane view. Or alternatively, the supporting structure 30 may have a discontinuous frame shape (e.g. with slits/openings) of rectangular annulus, circular annulus, elliptical annulus, other suitable polygonal annulus in the plane view. In some embodiments, a material of the supporting structure 30 includes an electrically conductive material, a thermally conductive material or an electrically and thermally conductive material. For example, the material of the supporting structure 30 includes metals or metal alloys, such as copper, aluminum, cobalt, copper coated with nickel, stainless steel, tungsten, copper-tungsten, copper-molybdenum, silver diamond, copper diamond, aluminum nitride, aluminum silicon carbide or their alloys, stacking of different material combinations thereof, or the like. For example, the supporting structure 30 is made of a material having high thermal conductivity between about 200 W/(m·K) to about 400 W/(m·K) or more. In the embodiments of which the supporting structure 30 has the high thermal conductivity, the heat dissipation of the semiconductor package SP2 is further enhanced.

A material of the bonding element 40 is not particularly limited, and may be chosen as a function of a material used for adhering the circuit substrate 60 and the supporting structure 30, where the bonding element 40 has to secure the circuit substrate 60 and the supporting structure 30 together. In some embodiments, the bonding element 40 includes an electrically conductive adhesive, a thermally conductive adhesive, or an electrically and thermally conductive adhesive. The material of the bonding element 40 may include a thermo-curable adhesive, photocurable adhesive, thermally conductive adhesive, thermosetting resin, waterproof adhesive, lamination adhesive or a combination thereof. In alternative embodiments, the bonding element 40 includes a die attach film (DAF). According to the type of material used, the bonding element 40 may be formed by deposition, lamination, printing, plating, or any other suitable technique. The bonding element 40 may further include a filler. For example, the filler includes a metal filler or a metal alloy filler. Through the bonding element 40, the supporting structure 30 is physically connect to the circuit substrate 60, for example. The disclosure is not limited thereto.

In certain embodiments, depending on the material of the bonding element 40, the circuit substrate 60 may be thermally and/or electrically coupled to supporting structure 30 through the bonding element 40. Through the bonding element 40, the supporting structure 30 may be thermally connected to the circuit substrate 60. Through the bonding element 40, the supporting structure 30 may be electrically connected to the circuit substrate 60. Through the bonding element 40, the supporting structure 30 may be thermally and electrically connected to the circuit substrate 60. In some embodiments, the shape of the bonding element 40 and the shape of the supporting structure 30 in the plane view (e.g. in FIG. 23) share the same pattern/profile. The supporting structure 30 is electrically isolated from the CoW structure 10A, in some embodiments.

In some embodiments, after the supporting structure 30 is mounted onto the circuit substrate 60, an illustrated top surface of the CoW structure 10A is lower than an illustrated top surface of the supporting structure 30 by a non-distance (e.g. being greater than zero). With such, the supporting structure 30 further provides a protection for the CoW structure 10A from physical damages during transportation, transferring and/or operation. Although not shown, the illustrated top surface of the CoW structure 10A may be higher than the illustrated top surface of the supporting structure 30 by a non-distance. Or alternatively, the illustrated top surface of the CoW structure 10A and the illustrated top surface of the supporting structure 30 may be located at the substantially same height-level. In some embodiments, the supporting structure 30 is electrically isolated to the CoW structure 10A. In that case, there is no electrical impact (e.g. negative effects such as noises or the like) induced by the supporting structure 30 to the CoW structure 10A.

After mounting the supporting structure 30 to the circuit substrate 60, the photonic components 9000 are removably installed onto the sockets 900 of the CoW structure 10A so to manufacture the semiconductor package SP2. The semiconductor package SP2 can be considered as a structure of chip-on-wafer-on-substrate (CoWoS). In other words, the semiconductor package SP2 is a CoWoS structure, for example. As shown in FIG. 22 and FIG. 23, the photonic components 9000 extend beyond the footprint areas of the optical dies 1000 and the supporting structure 300, for example.

In the above embodiments (e.g., 10A, SP1, and/or SP2), the interposer 5000A is included, which involves the bridge dies 5100 (e.g., 5100A, 5100B and/or 5100C), however the disclosure is not limited thereto, alternatively, the interposer 5000A may be substituted by an interposer 5000B which has no bridge dies (e.g., LSI dies) embedded therein. Referring FIG. 24 and FIG. 19 together, a CoW structure 10B depicted in FIG. 24 and the CoW structure 10A depicted in FIG. 19 are similar; the difference is that, the CoW structure 10B includes the interposer 5000B instead of the interposer 5000A. The elements similar to or substantially the same as the elements described above will use the same reference numbers, and certain details or descriptions of the same elements (e.g., the formations and materials) and the relationship thereof (e.g., the relative positioning configuration and electrical connection) will not be repeated herein.

In some embodiments, the interposer 5000B is a silicon interposer, where the interposer 5000B includes a core 5800, a plurality of conductive pillars 5200 penetrating through the core 5800, a redistribution circuit structure 5300 (e.g., including a dielectric structure 5320 and one or more metallization layers 5340) disposed on a first side of the core 5800 and electrically coupled to the conductive pillars 5200, a redistribution circuit structure 5400 (e.g., including a dielectric structure 5420 and one or more metallization layers 5440) disposed on a second side of the core 5800 and electrically coupled to the conductive pillars 5200, a plurality of conductive vias 5500 disposed over and electrically coupled to the redistribution circuit structure 5300, and a plurality of conductive terminals 5700 (e.g., including conductive connector 5720 and solder regions 5740 disposed thereon) disposed over and electrically coupled to the redistribution circuit structure 5400. In addition to or alternatively, the redistribution circuit structure 5300 and/or the redistribution circuit structure 5400 may be omitted. The interposer 5000B may include the core 5800, the conductive pillars 5200, the redistribution circuit structure 5300, the conductive vias 5500, and the conductive terminals 5700. Alternatively, the interposer 5000B may include the core 5800, the conductive pillars 5200, the redistribution circuit structure 5400, the conductive vias 5500, and the conductive terminals 5700. Alternatively, the interposer 5000B may include the core 5800, the conductive pillars 5200, the conductive vias 5500, and the conductive terminals 5700. In addition to or alternatively, the conductive vias 5500 may be omitted. The interposer 5000B may be referred to as an interconnect substrate, an interconnect structure, an interconnection substrate or an interconnection structure. The details of the conductive pillars 5200, the redistribution circuit structure 5300, the redistribution circuit structure 5400, the conductive vias 5500 and the conductive terminals 5700 have been previously discussed in FIG. 14, the formation and material of the core 5800 may be similar to or substantially identical to the formation and material of the substrate 5110 have been previously discussed in FIG. 14 and FIG. 15, and thus are not repeated herein for brevity.

Similarly, referring FIG. 25 and FIG. 20 together, a semiconductor package SP3 depicted in FIG. 25 and the semiconductor package SP1 depicted in FIG. 20 are similar; the difference is that, the semiconductor package SP3 includes the interposer 5000B instead of the interposer 5000A. On the other hand, referring FIG. 26 and FIG. 22 together, a semiconductor package SP4 depicted in FIG. 26 and the semiconductor package SP2 depicted in FIG. 22 are similar; the difference is that, the semiconductor package SP4 includes the interposer 5000B instead of the interposer 5000A. The disclosure is not specifically limited to the types of the interposer (e.g., 5000A and/or 5000B) and/or the types of the circuit substrate (e.g., 60).

In accordance with some embodiments, a semiconductor package includes an interposer, a semiconductor die, an optical die, a socket and a photonic component. The semiconductor die is disposed over the interposer. The optical die is disposed over the interposer and laterally next to the semiconductor die, where the optical die includes an edge coupler, a first reflector optically coupled to the edge coupler, and a first lens structure optically coupled to the edge coupler through the first reflector, the first reflector is laterally next to the edge coupler, and the first lens structure is vertically disposed over the first reflector. The socket is disposed over the optical die, where the optical die is between the socket and the interposer. The photonic component is removably installed onto the socket, where the photonic component includes a second reflector and a second lens structure optically coupled to the second reflector, and the second reflector is vertically disposed over the second lens structure. The second lens structure and the first lens structure are overlapped with and optically coupled to each other.

In accordance with some embodiments, a semiconductor package includes an interposer, a plurality of semiconductor dies, a plurality of optical dies, a plurality of sockets, a dielectric material and a plurality of optical fibers. The plurality of semiconductor dies and the plurality of optical dies are disposed over the interposer, where the plurality of optical dies are equipped with edge couplers, respectively. The plurality of sockets are disposed on the plurality of optical dies and each includes a protrusion. The dielectric material is disposed on the interposer and further cover sidewalls of the plurality of semiconductor dies, sidewalls of the plurality of optical dies and sidewall of the plurality of sockets. The plurality of optical fibers are disposed over the plurality of optical dies and respectively engaged with the protrusions of the plurality of sockets, where the plurality of sockets are disposed between the plurality of optical fibers and the plurality of optical dies, and the plurality of optical fibers are optically coupled to the edge couplers.

In accordance with some embodiments, a method of manufacturing a semiconductor package includes the following steps: providing an optical die and a semiconductor die, the optical die equipped with an edge coupler, a first reflector and a first lens structure being optically coupled to each other; mounting the optical die and the semiconductor die to an interposer; disposing a protective structure on the optical die, the protective structure engaging with the first lens structure of the optical die; forming a dielectric material over the interposer to fill gaps between optical die, the semiconductor die and the interposer, the dielectric material further extending onto a sidewall of the protective structure; removing the protective structure from the optical die; disposing a socket over the optical die, the socket comprising an opening corresponding to the first lens structure and a protrusion protruding away from the optical die; and installing an optical fiber onto the socket, the protrusion being partially inserted into the optical fiber, the optical fiber comprising a second reflector and a second lens structure optically coupled to the second reflector, wherein the second lens structure is optically coupled to the first lens structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
an interposer;
a semiconductor die, disposed over the interposer;
an optical die, disposed over the interposer and laterally next to the semiconductor die, wherein the optical die comprises an edge coupler, a first reflector optically coupled to the edge coupler, and a first lens structure optically coupled to the edge coupler through the first reflector, the first reflector is laterally next to the edge coupler, and the first lens structure is vertically disposed over the first reflector;
a socket, disposed over the optical die, the optical die being between the socket and the interposer; and
a photonic component, removably installed onto the socket, wherein the photonic component comprises a second reflector and a second lens structure optically coupled to the second reflector, and the second reflector is vertically disposed over the second lens structure, wherein the second lens structure and the first lens structure are overlapped with and optically coupled to each other.

2. The semiconductor package of claim 1, wherein the photonic component comprises an optical fiber.

3. The semiconductor package of claim 1, wherein the socket comprises a protrusion, and the protrusion is partially inserted into the photonic component being removably installed onto the socket.

4. The semiconductor package of claim 1, wherein the first reflector comprises a two-layer structure.

5. The semiconductor package of claim 4, wherein the first reflector comprises a first metal layer and a second metal layer disposed over the first metal layer, and the first metal layer is laterally disposed between the edge coupler and the second metal layer,
wherein a first thickness of the first metal layer is less than a second thickness of the second metal layer.

6. The semiconductor package of claim 1, further comprising at least one of
an insulating encapsulant, laterally encapsulating the semiconductor die and the optical die; or
an underfill, disposed in gaps between the semiconductor die and the interposer and the optical die and the interposer.

7. The semiconductor package of claim 1, wherein the semiconductor die and the optical die are disposed at a same side of the interposer and are electrically communicated to each other through the interposer.

8. A semiconductor package, comprising:
a plurality of semiconductor dies and a plurality of optical dies, disposed over an interposer, wherein the plurality of optical dies are equipped with edge couplers, respectively;
a plurality of sockets, disposed on the plurality of optical dies and each comprising a protrusion;
a dielectric material, disposed on the interposer and further covering sidewalls of the plurality of semiconductor dies, sidewalls of the plurality of optical dies and sidewall of the plurality of sockets; and
a plurality of optical fibers, disposed over the plurality of optical dies and respectively engaged with the protrusions of the plurality of sockets, wherein the plurality of sockets are disposed between the plurality of optical fibers and the plurality of optical dies, and the plurality of optical fibers are optically coupled to the edge couplers.

9. The semiconductor package of claim 8, wherein each of the plurality of optical dies comprises:
a photonic integrated circuit component, comprising an interconnect structure having a first surface and a second surface opposite to the first surface and the edge coupler disposed inside the interconnect structure;
an electric integrated circuit component, disposed over the second surface of the photonic integrated circuit component;
a supporting structure, disposed over the electric integrated circuit component and comprising a first lens structure at a surface of the supporting structure opposite to the electric integrated circuit component, wherein the electric integrated circuit component is between the photonic integrated circuit component and the supporting structure;
a redistribution circuit structure, disposed over the first surface of the photonic integrated circuit component;
a first reflecting structure, disposed in the redistribution circuit structure and further in contact with a patterned surface of the interconnect structure being adjacent next to the edge coupler, wherein the patterned surface is a slant surface in relation to the second surface; and
a plurality of conductive terminals, disposed over and connected to the redistribution circuit structure, wherein the redistribution circuit structure is between the photonic integrated circuit component and the plurality of conductive terminals.

10. The semiconductor package of claim 9, wherein an angle between the patterned surface and the second surface is about 45 degrees.

11. The semiconductor package of claim 9, wherein a surface roughness of the patterned surface is less than or substantially equal to about 15Å.

12. The semiconductor package of claim 9, wherein the first reflecting structure comprises:
a first metal layer, having a first thickness; and
a second metal layer, disposed between the first metal layer and the edge coupler, and having a second thickness,
wherein the second thickness is less than the first thickness.

13. The semiconductor package of claim 8, wherein a thickness of the protrusions approximately ranges from 300 μm to 500 μm.

14. The semiconductor package of claim 8, wherein each of the plurality of plurality of optical fibers comprises a second lens structure disposed at a surface thereof and a second reflecting structure embedded therein,
wherein the first lens structure is optically coupled to the second lens structure in a first direction, and an angel between a plane which the second reflecting structure located at and the first direction is about 45 degrees.

15. The semiconductor package of claim 8, further comprising a circuit substrate bonded to the interposer, wherein the interposer is disposed between the circuit substrate and the optical die and between the circuit substrate and the semiconductor die.

16. A method of manufacturing a semiconductor package, comprising:
providing an optical die and a semiconductor die, the optical die equipped with an edge coupler, a first reflector and a first lens structure being optically coupled to each other;
mounting the optical die and the semiconductor die to an interposer;
disposing a protective structure on the optical die, the protective structure engaging with the first lens structure of the optical die;
forming a dielectric material over the interposer to fill gaps between optical die, the semiconductor die and the interposer, the dielectric material further extending onto a sidewall of the protective structure;
removing the protective structure from the optical die;
disposing a socket over the optical die, the socket comprising an opening corresponding to the first lens structure and a protrusion protruding away from the optical die; and
installing an optical fiber onto the socket, the protrusion being partially inserted into the optical fiber, the optical fiber comprising a second reflector and a second lens structure optically coupled to the second reflector, wherein the second lens structure is optically coupled to the first lens structure.

17. The method of claim 16, prior to providing the optical die, further comprising:
forming the optical die, further comprising:
providing a photonic integrated circuit component, the photonic integrated circuit component comprising an interconnect structure and the edge coupled embed inside the interconnect structure;
bonding an electric integrated circuit component to the photonic integrated circuit component;
encapsulating the electric integrated circuit component with an encapsulant;
forming a first anti-reflecting coating layer over the encapsulant and the electric integrated circuit component;
disposing a supporting structure over the first anti-reflecting coating layer;
patterning the supporting structure to form the first lens structure at an outermost surface of the supporting structure;
forming a second anti-reflecting coating layer over the first lens structure;
patterning the interconnect structure to obtain a patterned surface being tilted from a surface of the interconnect structure disposed with the electric integrated circuit component, the patterned surface is laterally next to the edge coupler; and
forming a redistribution circuit structure over the interconnect structure of the photonic integrated circuit component and covering the patterned surface, the photonic integrated circuit component being between the electric integrated circuit component and the redistribution circuit structure, wherein the first reflector is formed in a form of two-layer structure during forming the redistribution circuit structure, and the first reflector is laid on the patterned surface of the interconnect structure so to optically coupled to the edge coupler in a horizontal direction and optically coupled to the first lens structure in a vertical direction.

18. The method of claim 17, wherein installing the optical fiber onto the socket comprises removably installing the optical fiber onto the socket, wherein the second lens structure is optically coupled to the first lens structure in the vertical direction, and the second reflector is optically coupled to the second lens structure in the horizontal direction.

19. The method of claim 16, prior to installing the optical fiber onto the socket and after disposing the socket over the optical die, further comprising:
mounting the interposer to a circuit substrate, the interposer being between the circuit substrate and the optical die and between the circuit substrate and the semiconductor die.

20. The method of claim 16, wherein mounting the optical die and the semiconductor die to the interposer by flip-chip bonding, and the optical die and the semiconductor die are located at one side of the interposer.
